(19) United States
(12) Patent Application Publication
(10) Pub. No.: US 2019/0312235 A1
(43) Pub. Date: Oct. 10, 2019

(54) ORGANIC ELECTROLUMINESCENT ELEMENT, ORGANIC ELECTROLUMINESCENT PANEL, AND ELECTRONIC APPARATUS

(71) Applicant: JOLED INC., Tokyo (JP)

(72) Inventors: KENTA FUKUOKA, Tokyo (JP); JIRO YAMADA, Tokyo (JP); HIDEKI KOBAYASHI, Tokyo (JP); KENICHI NENDAI, Tokyo (JP); AKIFUMI OKIGAWA, Tokyo (JP)

(21) Appl. No.: 16/290,071

(22) Filed: Mar. 1, 2019

(30) Foreign Application Priority Data
Apr. 9, 2018 (JP) 2018-074967

(51) Int. Cl. H01L 51/52; H01L 27/32; H01L 51/50; G09G 3/3233

(52) U.S. Cl. CPC H01L 51/5271; H01L 51/5275; H01L 27/3246; G09G 2300/0452; H01L 51/5012; G09G 3/3233; G09G 2320/0233; H01L 27/3211

(57) ABSTRACT

An organic electroluminescent element includes, in order, a substrate, a first electrode layer, a light-emitting layer, a second electrode layer, a first refractive index layer, and a second refractive index layer. The first refractive index layer and the second refractive index layer are in contact with each other at an interface. The light-emitting layer has a light-emitting region opposed to the first electrode layer. The interface has a recess opposed to the light-emitting region.

### CROSS REFERENCE TO RELATED APPLICATIONS

This application claims the benefit of Japanese Priority Patent Application No. 2018-074967 filed on Apr. 9, 2018, the entire contents of which are incorporated herein by reference.

### BACKGROUND

The disclosure relates to an organic electroluminescent element, an organic electroluminescent panel, and an electronic apparatus.

A variety of organic electroluminescent units, such as organic electroluminescent displays, that includes organic electroluminescent elements have been proposed. Reference is made to Japanese Unexamined Patent Application Publication No. 2017-072812, for example.

### SUMMARY

It is generally desired that an organic electroluminescent unit have improved front luminance.

It is desirable to provide an organic electroluminescent element having improved front luminance, and an organic electroluminescent panel and an electronic apparatus each including such an organic electroluminescent element.

An organic electroluminescent element according to one embodiment of the disclosure includes, in order, on a substrate, a first electrode layer, a light-emitting layer, a second electrode layer, a first refractive index layer, and a second refractive index layer. The first refractive index layer and the second refractive index layer are in contact with each other to form an interface. The light-emitting layer has a light-emitting region opposed to the first electrode layer. The interface has a recess opposed to the light-emitting region.

An organic electroluminescent panel according to one embodiment of the disclosure includes a plurality of pixels. The pixels each include an organic electroluminescent element. The organic electroluminescent element includes, in order, a substrate, a first electrode layer, a light-emitting layer, a second electrode layer, a first refractive index layer, and a second refractive index layer. The first refractive index layer and the second refractive index layer are in contact with each other at an interface. The light-emitting layer has one or more light-emitting regions opposed to the first electrode layer. The interface has one or more recesses opposed to the one or more light-emitting regions.

An electronic apparatus according to one embodiment of the disclosure includes an organic electroluminescent panel including a plurality of pixels, the pixels each including an organic electroluminescent element, and a driving circuit configured to drive the organic electroluminescent panel. The organic electroluminescent panel includes, in order, on a substrate, a first electrode layer, a light-emitting layer, a second electrode layer, a first refractive index layer, and a second refractive index layer. The first refractive index layer and the second refractive index layer are in contact with each other at an interface. The light-emitting layer has a light-emitting region opposed to the first electrode layer. The interface has a recess opposed to the light-emitting region.

### BRIEF DESCRIPTION OF THE DRAWINGS

The accompanying drawings are included to provide a further understanding of the disclosure and are incorporated in and constitute a part of this specification. The drawings illustrate example embodiments and, together with the specification, serve to explain the principles of the disclosure.

FIG. 1 is a schematic view of an example configuration of an organic electroluminescent unit according to one embodiment of the disclosure.

FIG. 2 is an example circuit diagram of a subpixel in each pixel illustrated in FIG. 1.

FIG. 3 is a schematic view of an example configuration of an organic electroluminescent panel illustrated in FIG. 1.

FIG. 4 is a cross-sectional view of an example configuration of the organic electroluminescent panel taken along the line A-A in FIG. 3.

FIG. 5 is a cross-sectional view of an example configuration of the organic electroluminescent panel taken along the line B-B in FIG. 3.

FIG. 6 is a cross-sectional view of an example configuration of the organic electroluminescent panel taken along the line C-C in FIG. 3.

FIG. 7 is a schematic view of an example configuration of the organic electroluminescent panel of FIG. 1 according to one modification example.

FIG. 8 is a partially enlarged view of the organic electroluminescent panel of FIG. 4.

FIG. 9 is a diagram illustrating an example relation of refractive indices of a protection layer and a sealing layer versus a magnification of light emission efficiency obtained by a recess having a lens effect relative to light emission efficiency obtained in a case having no lens effect.

FIG. 10 is a diagram illustrating an example relation between the depth of an opening and light emission efficiency.

FIG. 11 is a diagram illustrating an example relation between the depth of the opening and light emission efficiency.

FIG. 12 is a diagram illustrating an example relation between a refractive index of the sealing layer and light emission efficiency of a red pixel.

FIG. 13 is a diagram illustrating an example relation between a refractive index of the sealing layer and light emission efficiency of a green pixel.

FIG. 14 is a diagram illustrating an example relation between a refractive index of the sealing layer and light emission efficiency of a blue pixel.

FIG. 15 is a diagram illustrating an example viewing angle characteristic along a longitudinal direction of the red pixel.

FIG. 16 is a diagram illustrating an example viewing angle characteristic along the longitudinal direction of the green pixel.

FIG. 17 is a diagram illustrating an example viewing angle characteristic along the longitudinal direction of the blue pixel.

FIG. 18 is a diagram illustrating an example viewing angle characteristic along a lateral direction of the red pixel.

FIG. 19 is a diagram illustrating an example viewing angle characteristic along the lateral direction of the green pixel.

FIG. 20 is a diagram illustrating an example viewing angle characteristic along the lateral direction of the blue pixel.

FIG. 21 is a cross-sectional view of an example configuration of the organic electroluminescent panel taken along the line A-A in FIG. 3 according to one modification example.

FIG. 22 is a cross-sectional view of an example configuration of the organic electroluminescent panel taken along the line B-B in FIG. 3 according to one modification example.

FIG. 23 is a cross-sectional view of an example configuration of the organic electroluminescent panel taken along the line C-C in FIG. 3 according to one modification example.

FIG. 24 is a cross-sectional view of an example configuration of an organic electroluminescent element in each subpixel illustrated in FIGS. 21 to 23.

FIG. 25 is a cross-sectional view of an example configuration of the organic electroluminescent element in each subpixel illustrated in FIGS. 21 to 23.

FIG. 26 is a cross-sectional view of an example configuration of the organic electroluminescent element in each subpixel illustrated in FIGS. 21 to 23.

FIG. 27 is a schematic view of an example configuration of the organic electroluminescent panel of FIG. 1 according to one modification example.

FIG. 28 is a schematic view of an example configuration of the organic electroluminescent panel of FIG. 1 according to one modification example.

FIG. 29 is a perspective view of an example appearance of an electronic apparatus provided with the organic electroluminescent unit according to one example embodiment of the disclosure.

FIG. 30 is a perspective view of an example appearance of an illumination apparatus provided with the organic electroluminescent element according to one example embodiment of the disclosure.

### DETAILED DESCRIPTION

In the following, some example embodiments of the disclosure are described in detail, in the following order, with reference to the accompanying drawings. Note that the following description is directed to illustrative examples of the disclosure and not to be construed as limiting to the disclosure. Factors including, without limitation, numerical values, shapes, materials, components, positions of the components, and how the components are coupled to each other are illustrative only and not to be construed as limiting to the disclosure. Further, elements in the following example embodiments which are not recited in a most-generic independent claim of the disclosure are optional and may be provided on an as-needed basis. The drawings are schematic and are not intended to be drawn to scale. Note that the like elements are denoted with the same reference numerals, and any redundant description thereof will not be described in detail.

### 1. EMBODIMENT

### Configuration

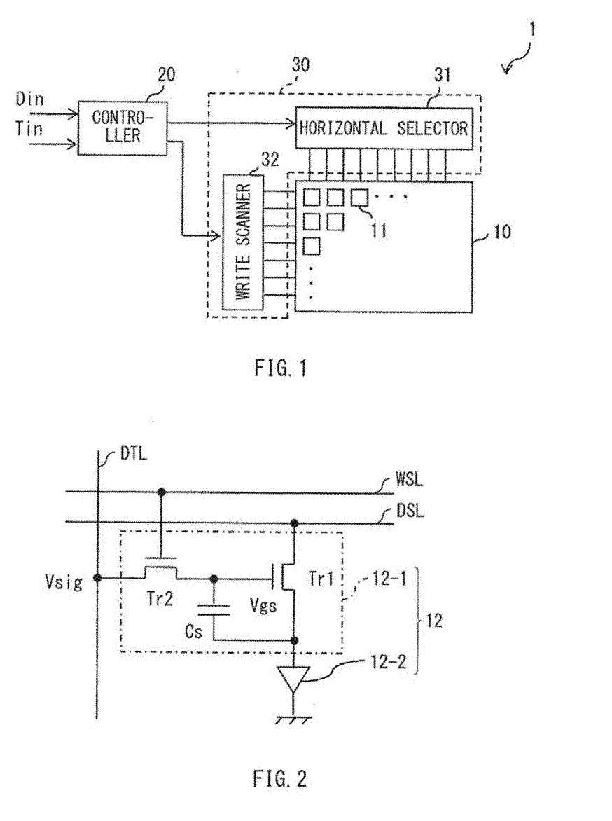

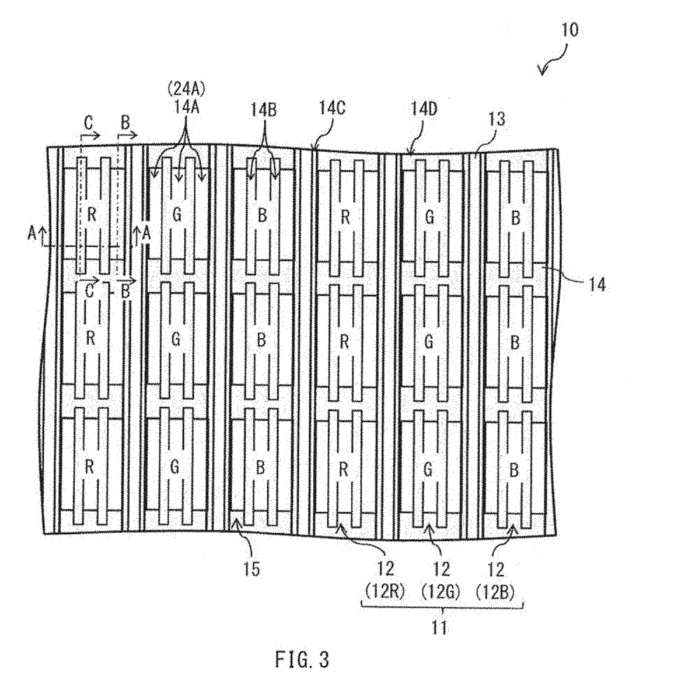

FIG. 1 is a schematic view of an example configuration of an organic electroluminescent unit 1 according to an example embodiment of the disclosure. FIG. 2 is an example circuit diagram of a subpixel 12 in each pixel 11 in the organic electroluminescent unit 1. The organic electroluminescent unit 1 may include, for example, an organic electroluminescent panel 10, a controller 20, and a driver 30. The driver 30 may be mounted on an outer edge portion of the organic electroluminescent panel 10, for example. The organic electroluminescent panel 10 includes a plurality of pixels 11 disposed in matrix. The controller 20 and the driver 30 may drive the organic electroluminescent panel 10 (i.e., pixels 11) on the basis of an external image signal Din and an external synchronizing signal Tin.

### Organic Electroluminescent Panel 10

In response to the active-matrix driving of the pixels 11 performed by the controller 20 and the driver 30, the organic electroluminescent panel 10 may display an image based on the external image signal Din and the external synchronizing signal Tin. The organic electroluminescent panel 10 may include a plurality of scanning lines WSL extending in a row direction, a plurality of power lines DSL extending in the row direction, a plurality of signal lines DTL extending in a column direction, and the plurality of pixels 11 arranged in matrix.

The scanning lines WSL may be used to select the pixels 11. In an example, the scanning lines WSL supply the respective pixels 11 with a selection pulse Pw to select the pixels 11 on a predetermined unit basis, for example, a pixel-row basis. The signal lines DTL may be used to supply the respective pixels 11 with a data pulse that includes a signal voltage Vsig based on the image signal Din. The power lines DSL may be used to supply the respective pixels 11 with electric power.

Each of the pixels 11 may include, for example, a subpixel 12 emitting red light, a subpixel 12 emitting green light, and a subpixel 12 emitting blue light. Each of the pixels 11 may further include a subpixel 12 that emits light of another color, such as white or yellow, for example. The subpixel 12 may be aligned in line along a predetermined direction in each of the pixel 11, for example.

Each of the signal lines DTL may be coupled to an output terminal of a horizontal selector 31 described below. Each of the signal lines DTL may be allocated to its corresponding pixel column, for example. Each of the scanning lines WSL may be coupled to an output terminal of a write scanner 32 described below. Each of the scanning lines WSL may be allocated to its corresponding pixel row, for example. Each of the power lines DSL may be coupled to an output terminal of a power source. Each of the power lines DSL may be allocated to its corresponding pixel rows, for example.

Each of the subpixels 12 may include a pixel circuit 12-1 and an organic electroluminescent element 12-2. An example configuration of the organic electroluminescent element 12-2 is described in detail below.

The pixel circuit 12-1 may control light emission and light extinction of the organic electroluminescent element 12-2. The pixel circuit 12-1 may hold a voltage written into the subpixel 12 by write scanning described below. The pixel circuit 12-1 may include, for example, a driving transistor Tr1, a switching transistor Tr2, and a storage capacitor Cs.

The switching transistor Tr2 may control application of the signal voltage Vsig to a gate of the driving transistor Tr1. The signal voltage Vsig may correspond to the image signal Din. For example, the switching transistor Tr2 may sample a voltage of the signal line DTL, and may write the sampled voltage to the gate of the driving transistor Tr1. The driving transistor Tr1 may be coupled in series to the organic electroluminescent element 12-2. The driving transistor Tr1 may drive the organic electroluminescent element 12-2. The driving transistor Tr1 may control an electrical current flowing in the organic electroluminescent element 12-2 on the basis of a magnitude of the voltage sampled by the switching transistor Tr2. The storage capacitor Cs may hold a predetermined voltage between the gate and a source of the driving transistor Tr1. The storage capacitor Cs may hold a voltage Vgs between the gate and the source of the driving transistor Tr1 at a constant level for a predetermined period of time. Note that the pixel circuit 12-1 may have the 2Tr1C circuit configuration described above and additional capacitors and transistors. Alternatively, the pixel circuit 12-1 may have a circuit configuration different from the 2Tr1C circuit configuration described above.

Each of the signal lines DTL may be coupled to the output terminal of the horizontal selector 31 described below and the source or drain of the switching transistor Tr2. Each of the scanning lines WSL may be coupled to the output terminal of the write scanner 32 described below and the gate of the switching transistor Tr2. Each of the power lines DSL may be coupled to a power supply circuit and the source or the drain of the driving transistor Tr1.

The gate of the switching transistor Tr2 may be coupled to the scanning line WSL. One of the source or drain of the switching transistor Tr2 may be coupled to the signal line DTL. The other of the source or drain, uncoupled to the signal line DTL, of the switching transistor Tr2 may be coupled to the gate of the driving transistor Tr1. One of the source or drain of the driving transistor Tr1 may be coupled to the power line DSL. The other of the source or drain, uncoupled to the power line DSL, of driving transistor Tr1 may be coupled to the anode 21 of the organic electroluminescent element 21-2. One terminal of the storage capacitor Cs may be coupled to the gate of the driving transistor Tr1. The other end of the storage capacitor Cs may be coupled to one of the source or drain, adjacent to the organic electroluminescent element 21-2, of the driving transistor Tr1.

### Driver 30

The driver 30 may include, for example, the horizontal selector 31 and the write scanner 32. The horizontal selector 31 may apply an analog signal voltage Vsig received from the controller 20 to each of the signal lines DTL in response to (in synchronization with) an input of a control signal, for example. The write scanner 32 may scan the subpixels 12 on a predetermined unit basis.

### Controller 20

The controller 20 will now be described. The controller 20 may perform a predetermined correction of a digital image signal Din received from an external device, and may generate a signal voltage Vsig on the basis of the corrected image signal. The controller 20 may output the generated signal voltage Vsig to the horizontal selector 31, for example. The controller 20 may output a control signal to each circuit in the driver 30 in response to (in synchronization with) a synchronizing signal Tin received from an external device.

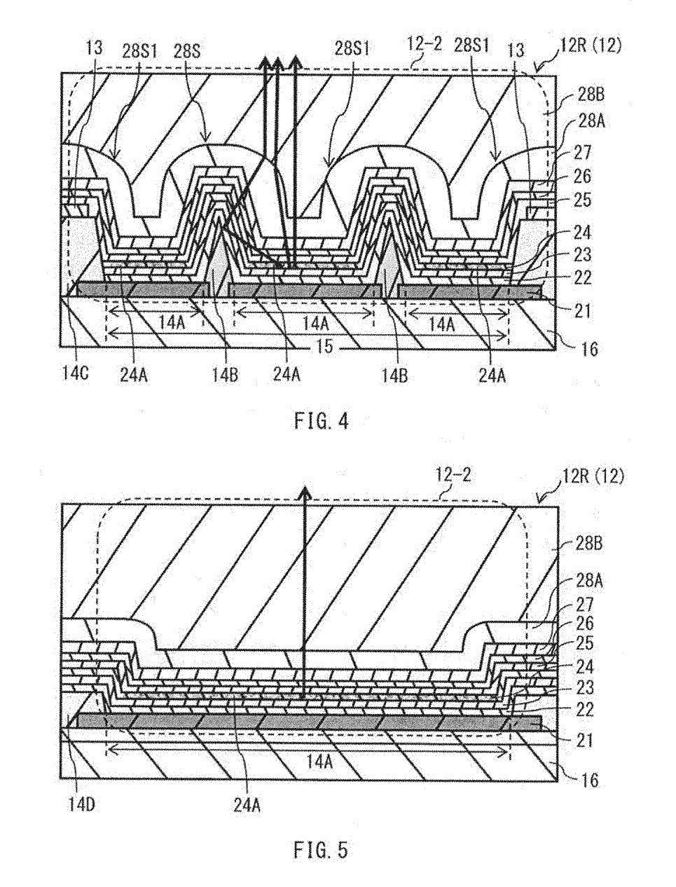

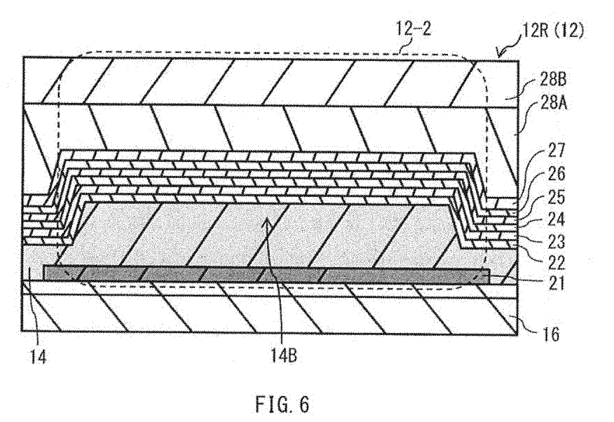

The organic electroluminescent element 12-2 will now be described with reference to FIGS. 3 to 6. FIG. 3 schematically illustrates an example configuration of the organic electroluminescent panel 10. FIG. 4 illustrates an example cross-sectional configuration of the organic electroluminescent panel 10 taken along the line A-A in FIG. 3 (i.e., an example cross-sectional configuration of the subpixel 12 (12R) along a row direction). FIG. 5 illustrates an example cross-sectional configuration of the organic electroluminescent panel 10 taken along the line B-B in FIG. 3 (i.e., an example cross-sectional configuration of the subpixel 12 (12R) along a column direction). FIG. 6 illustrates an example cross-sectional configuration of the organic electroluminescent panel 10 taken along the line C-C in FIG. 3 (i.e., an example cross-sectional configuration of the subpixel 12 (12R) along the column direction). Note that FIG. 5 illustrates an example cross-sectional configuration of a portion of the organic electroluminescent panel 10 not including crosspieces 14B described below. FIG. 6 illustrates an example cross-sectional configuration of a portion of the organic electroluminescent panel 10 including the crosspieces 14B.

The organic electroluminescent panel 10 may include the pixels 11 that are arranged in matrix. As described above, each of the pixels 11 may include, for example, the subpixel 12 (12R) emitting red light, the subpixel 12 (12G) emitting green light, and the subpixel 12 (12B) emitting blue light.

The subpixel 12R may include the organic electroluminescent element 12-2 (12r) emitting red light. The subpixel 12G may include the organic electroluminescent element 12-2 (12g) emitting green light. The subpixel 12B may include the organic electroluminescent element 12-2 (12b) emitting blue light. The subpixels 12R, 12G, and 12B may be arranged in a stripe pattern. In each of the pixels 11, the subpixels 12R, 12G, and 12B may be arranged along the row direction, for example. Additionally, the subpixels 12 emitting light of the same color may be arranged along the column direction in each pixel column, for example.

The organic electroluminescent panel 10 includes a substrate 16. The substrate 16 may include a base and a wiring layer provided on the base. The base may support, for example, the organic electroluminescent elements 12-2, an insulating layer 14, column regulators 14C described below, and row regulators 14D described below. The base of the substrate 16 may include, for example, non-alkali glass, soda glass, nonfluorescent glass, phosphate glass, borate glass, or quartz. Alternatively, the base of the substrate 16 may include, for example, acrylic resin, styrene resin, polycarbonate resin, epoxy resin, polyethylene, polyester, silicone resin, or alumina. The wiring layer of the substrate 16 may include, for example, the pixel circuits 12-1 of the respective pixels 11.

The organic electroluminescent panel 10 may further include the insulating layer 14 on the substrate 16. The insulating layer 14 may correspond to a specific but non-limiting example of “pedestal” according to one embodiment of the disclosure. The insulating layer 14 may define each of the subpixels 12. In one example, an upper limit thickness of the insulating layer 14 may be within a range that allows for shape control of the insulating layer 14 during the manufacture of the insulating layer 14, in consideration of variations in film thickness and control of a bottom line width. For example, the upper limit thickness of the insulating layer 14 may be 10 μm or smaller. In another example, the upper limit thickness of the insulating layer 14 may be within a range that suppresses an increase in tact time with an increase in exposure time in an exposing process and that suppresses a reduction in productivity on mass production lines. For example, the upper limit thickness of the insulating layer 14 may be 7 μm or smaller. Additionally, a lower limit thickness of the insulating layer 14 may be determined on the basis of resolution limits of an exposure device and a material of the insulating layer 14, for example. One reason for this is that as the film thickness becomes thinner, the bottom line width is to be adjusted to substantially the same extent as the film thickness, in this example. In one example where the insulating layer 14 is manufactured using a semiconductor stepper, the lower limit thickness of the insulating layer 14 may be 1 μm or greater. In another example where the insulating layer 14 may be manufactured using a flat-panel stepper and a scanner, the lower limit thickness of the insulating layer 14 may be 2 μm or greater. Accordingly, the insulating layer 14 may have a thickness within a range from 1 μm to 10 μm. Alternatively, the insulating layer 14 may have a thickness within a range from 2 μm to 7 μm.

The insulating layer 14 may include a plurality of column regulators 14C and a plurality of row regulators 14D. The column regulators 14C and the row regulators 14D may define each of the subpixels 12. Each of the column regulators 14C may extend in the column direction, and each of the row regulators 14D may extend in the row direction. The column regulators 14C extending in the column direction may be disposed side by side to each other at a predetermined interval along the row direction. The row regulators 14D extending in the row direction may be disposed side by side to each other at a predetermined interval along the column direction. The column regulators 14C may intersect the respective row regulators 14D to form a grid-pattern. For example, the column regulators 14C may be orthogonal to the respective row regulators 14D. Each of the subpixels 12 may be surrounded by two of the column regulators 14C that are adjacent to each other and two of the row regulators 14D that are adjacent to each other. In other words, each of the subpixels 12 may be defined by two of the column regulators 14C that are adjacent to each other and two of the row regulators 14D that are adjacent to each other.

The insulating layer 14 may include a plurality of (e.g., two) crosspieces 14B that extend in the column direction in each of the subpixels 12. The crosspieces 14B extending in the column direction may be disposed side by side to each other at a predetermined interval along the row direction. The insulating layer 14 may further include a plurality of (e.g., three) slit-shaped openings 14A in a region surrounded by two of the column regulators 14C that are adjacent to each other and two of the row regulators 14D that are adjacent to each other and not including the crosspieces 14B. A surface of an anode 21 described below may be exposed at the bottom of each of the openings 14A. This allows holes supplied from the anode 21 exposed at the bottom of each of the openings 14A to be recombined with respective electrons supplied from a cathode 27 in a light-emitting layer 24 described below, causing the light-emitting layer 24 to emit light. Accordingly, the light-emitting layer 24 may have light-emitting regions 24A opposed to the respective openings 14A. In other words, the light-emitting regions 24A may be generated in regions of the light-emitting layer 24 opposed to the anode 21. In this embodiment, the light-emitting regions 24A of the light-emitting layer 24 in each of the subpixels 12 may each have an island shape, and may be surrounded by the insulating layer 14 including the column regulators 14C, the row regulators 14D, and the crosspieces 14B.

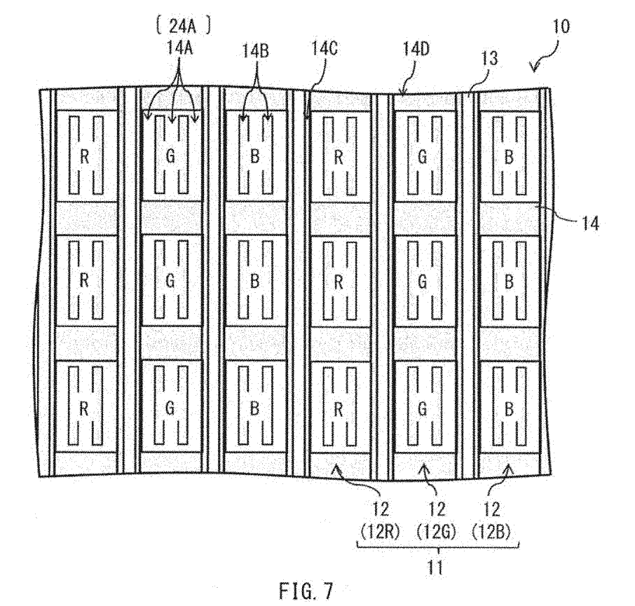

In one example, each of the crosspieces 14B may bridge two of the row regulators 14D that are adjacent to each other, as illustrated in FIGS. 3 to 6. In another example, the crosspiece 14B may be disposed separately from the two of the row regulators 14D that are adjacent to each other, as illustrated in FIG. 7. FIG. 7 schematically illustrates an example configuration of the organic electroluminescent panel 10.

The column regulators 14C, the row regulators 14D, and the crosspieces 14B may surround the light-emitting regions 24A, and may each have an upper surface positioned above the light-emitting regions 24A. In one example illustrated in FIGS. 3 to 6, for example, the row regulator 14D may have a height (from the substrate 16) smaller than that of the column regulator 14C. In this example, an array of the subpixels 12 along the column direction may be provided in a strip groove 15 defined by two of the column regulators 14C that are disposed on opposite sides of the array of the subpixels 12. Additionally, the subpixels 12 in the array may share the light-emitting layer 24 described below. In another example, the row regulator 14D may have a height equal to that of the column regulator 14C. In this example, each of the subpixels 12 may be provided in a dent defined by two of the column regulators 14C that are adjacent to each other and two of the row regulators 14D that are adjacent to each other, and may individually include the light-emitting layer 24.

In an example, each of the openings 14A may have a trapezoidal shape flaring upward in cross-sectional view along the row direction, as illustrated in FIG. 4. Additionally, each of the openings 14A may have a trapezoidal shape flaring upward in cross-sectional view along the column direction, as illustrated in FIG. 5, for example. Each of the openings 14A may have a reflective side face that reflects light emitted from the light-emitting regions 24A of the light-emitting layer 24 and raises the light toward a normal direction of the substrate 16. Provided that a protection layer 28A described below has a refractive index n1, and the insulating layer 14 has a refractive index n2, the refractive indices n1 and n2 may satisfy the following Expressions 1 and 2:

1.123 n1≤1.8 Expression 1

|n1−n2|≥0.20 Expression 2.

In one example, n2 may be within a range from 1.4 to 1.6. This enhances efficiency in extracting light emitted from the light-emitting layer 24 to the outside.

Additionally, the depth D of each of the openings 14A (i.e., the thickness of the insulating layer 14), the width Wh of the opening in the upper surface of the insulating layer 14, and the width WL of the opening in the lower surface of the insulating layer 14 may satisfy the following Expressions 3 and 4:

0.5≤WL/Wh≤0.8 Expression

0.5≤D/WL≤2.0 Expression 4.

Such a reflecting structure of the openings 14A of the insulating layer 14 that satisfies the conditions of shape and refractive index described above enhances efficiency in extracting light from the light-emitting layer 24. As a result, according to the examination by the inventors of the disclosure, the reflecting structure provides a 1.2 to 1.5-fold increase in luminance, compared with a case without the reflecting structure.

The insulating layer 14 may include, for example, an insulating organic material. Specific but non-limiting examples of the insulating organic material may include acrylic resin, polyimide resin, and novolac phenol resin. In one example, the insulating layer 14 may include an insulating resin that is resistant to heat and a solvent. The column regulators 14C and the row regulators 14D may be formed by processing an insulating resin into a desired pattern by means of photolithography and developing, for example. The column regulators 14C may each have a forward tapered shape in cross-sectional view, as illustrated in FIG. 4, for example. The row regulators 14D may each have a forward tapered shape in cross-sectional view, as illustrated in FIG. 5.

The organic electroluminescent panel 10 may include a plurality of line banks 13 on the insulating layer 14, for example. The line banks 13 may extend in the column direction and may be in contact with the upper surfaces of the column regulators 14C. The line banks 13 may each have a liquid-repellent characteristic. Accordingly, the line banks 13 suppress or prevent an inflow of ink from one subpixel 12 into another subpixel 12 having different color, during formation of the organic electroluminescent element 12-2 on the substrate 16.

Each of the organic electroluminescent elements 12-2 may include, in order, the substrate 16, the anode 21, a hole injection layer 22, a hole transport layer 23, the light-emitting layer 24, an electron transport layer 25, an electron injection layer 26, and the cathode 27, for example. The anode 21 may correspond to a specific but non-limiting example of “first electrode” according to one embodiment of the disclosure. The light-emitting layer 24 may correspond to a specific but non-limiting example of “light-emitting layer” according to one embodiment of the disclosure. The cathode 27 may correspond to a specific but non-limiting example of “second electrode” according to one embodiment of the disclosure.

The organic electroluminescent element 12-2 may include the anode 21, the light-emitting layer 24, and the cathode 27. The light-emitting layer 24 may be provided between the anode 21 and the cathode 27, for example. The organic electroluminescent element 12-2 may further include, in order from the anode 21, the hole injection layer 22 and the hole transport layer 23 that are provided between the anode 21 and the light-emitting layer 24, for example. Note that one or both of the hole injection layer 22 and the hole transport layer 23 may be omitted. The organic electroluminescent element 12-2 may further include, in order from the light-emitting layer 24, the electron transport layer 25 and the electron injection layer 26 that are provided between the light-emitting layer 24 and the cathode 27, for example. Note that one or both of the electron transport layer 25 and the electron injection layer 26 may be omitted. The organic electroluminescent element 12-2 may have a device structure that includes the anode 21, the hole injection layer 22, the hole transport layer 23, the light-emitting layer 24, the electron transport layer 25, the electron injection layer 26, and the cathode 27 in this order from the substrate 16. The organic electroluminescent element 12-2 may further include additional functional layers.

The hole injection layer 22 may enhance efficiency in injecting holes. The hole transport layer 23 may transport holes injected from the anode 21 to the light-emitting layer 24. The light-emitting layer 24 may emit light of a predetermined color through recombination of electrons and holes. The electron transport layer 25 may transport electrons injected from the cathode 27 to the light-emitting layer 24. The electron injection layer 26 may enhance efficiency in injecting electrons. One or both of the hole injection layer 22 and the electron injection layer 26 may be omitted. The organic electroluminescent element 12-2 may further include other layers in addition to the layers described above.

The anode 21 may be provided on the substrate 16, for example. In one example, an end portion of the anode 21 may be buried in the column regulators 14C and the row regulators 14D. In another example, the end portion of the anode 21 may be disposed in a region not including the column regulators 14C and the row regulators 14D. The anode 21 may be a reflective electrode having reflectivity. The anode 21 may be a reflective conductive film that includes an electrically-conductive material, such as aluminum (Al), platinum (Pt), gold (Au), chromium (Cr), tungsten (W), or an aluminum alloy. In this embodiment, the anode 21 may have a reflective surface serving as a reflective anode surface. Alternatively, the anode 21 may be a laminate that includes a transparent electrode and a reflective electrode provided on the transparent electrode.

The cathode 27 may be a semi-transmissive reflective electrode. The cathode 27 may include, for example, magnesium (Mg), silver (Ag), or an alloy thereof. In this embodiment, the cathode 27 may have a reflective surface serving as a semi-transmissive cathode surface. Alternatively, the cathode 27 may include a transparent electrically-conductive film and an Al thin-film that is provided on a surface of the transparent electrically-conductive film. The transparent electrically-conductive film may include, for example, a transparent electrically-conductive material, such as indium tin oxide (ITO) or indium zinc oxide (IZO). As described above, the anode 21 may have reflectivity, and the cathode 27 may have transparency. Accordingly, the organic electroluminescent element 12-2 may have a top-emission structure that emits light through the cathode 27.

The hole injection layer 22 may facilitate injection of holes from the anode 21 to the light-emitting layer 24. The hole injection layer 22 may include, for example, an oxide of silver (Ag), molybdenum (Mo), chromium (Cr), vanadium (V), tungsten (W), nickel (Ni), or iridium (Ir), or an electrically-conductive polymeric material, such as a mixture of polythiophene and polystyrene sulfonate (PEDOT). The hole injection layer 22 may be a single-layer film or multi-layer film.

The hole transport layer 23 may transport holes injected from the anode 21 to the light-emitting layer 24. The hole transport layer 23 may be a coated film, for example. In one example, the hole transport layer 23 may be formed by coating and drying a solution that includes an organic material having a hole transporting property (hereinafter referred to as “hole transporting material 23M”), as a main solute. The hole transport layer 23 may mainly, but not necessarily mainly include the hole transporting material 23M.

Specific but non-limiting examples of the hole transporting material 23M of the hole transport layer 23 may include an arylamine derivative, a triazole derivative, an oxadiazole derivative, an imidazole derivative, a polyarylalkane derivative, a pyrazoline derivative, a pyrazolone derivative, a phenylenediamine derivative, an amino-substituted chalcone derivative, an oxazole derivative, a styrylanthracene derivative, a fluorenone derivative, a hydrazone derivative, a stilbene derivative, a butadiene compound, a polystyrene derivative, a triphenylmethane derivative, a tetraphenylbenzene derivative, or any combination thereof. To achieve solubility and insolubilizing property, the hole transporting material 23M may further contain, in a molecular structure thereof, a soluble group, and an insoluble group, such as a thermal dissociation soluble group, a cross-linking group, or a removable protecting group, for example.

In the light-emitting layer 24, a hole injected from the anode 21 and an electron injected from the cathode 27 may be recombined with each other to generate an exciton in the light-emitting layer 24. This may cause the light-emitting layer 24 to emit light. The light-emitting layer 24 may be a coated layer, for example. In one example, the light-emitting layer 24 may be formed by coating and drying a solution that includes a solute that mainly, but not necessarily mainly includes an organic material generating excitons through the recombination of holes and electrons and thereby emitting light (hereinafter referred to as “organic luminescent material 24M”). The light-emitting layer 24 may mainly, but not necessarily mainly include the organic luminescent material 24M. The organic electroluminescent element 12r in the subpixel 12R may include the organic luminescent material 24M that includes a red organic luminescent material. The organic electroluminescent element 12g in the subpixel 12G may include the organic luminescent material 24M that includes a green organic luminescent material. The organic electroluminescent element 12b in the subpixel 12B may include the organic luminescent material 24M that includes a blue organic luminescent material.

The light-emitting layer 24 may have a monolithic organic light-emitting layer, or a laminate of a plurality of organic light-emitting layers, for example. In one example where the light-emitting layer 24 is a laminate of the organic light-emitting layers, the organic light-emitting layers may be coated layers that include a common main component. The organic light-emitting layers may be formed by coating and drying a solution that includes the organic luminescent material 24M as a main solute.

In one example, the organic luminescent material 24M of the light-emitting layer 24 may include a single dopant material. In another example, the organic luminescent material 24M may include a host material and a dopant material in combination. In other words, the light-emitting layer 24 may include, as the organic luminescent material 24M, the host material and the dopant material. The host material may serve to transport electrical charges of electrons or holes, and the dopant material may serve to emit light. In still another example, the organic luminescent material 24M may include two or more host materials and two or more dopant materials in combination. For example, the amount of the dopant material may be within a range from 0.01 weight percent to 30 weight percent relative to the amount of the host material. Alternatively, the amount of the dopant material may be within a range from 0.01 weight percent to 10 weight percent relative to the amount of the host material.

Specific but non-limiting examples of the host material of the light-emitting layer 24 may include an amine compound, a condensed polycyclic aromatic compound, and a heterocyclic compound. Specific but non-limiting examples of the amine compound may include a monoamine derivative, a diamine derivative, a triamine derivative, and a tetraamine derivative. Specific but non-limiting examples of the condensed polycyclic aromatic compound may include an anthracene derivative, a naphthalene derivative, a naphthacene derivative, a phenanthrene derivative, a chrysene derivative, a fluoranthene derivative, a triphenylene derivative, a pentacene derivative, and a perylene derivative. Specific but non-limiting examples of the heterocyclic compound may include a carbazole derivative, a furan derivative, a pyridine derivative, a pyrimidine derivative, a triazine derivative, an imidazole derivative, a pyrazole derivative, a triazole derivative, an oxazole derivative, an oxadiazole derivative, a pyrrole derivative, an indole derivative, an azaindole derivative, an azacarbazole derivative, a pyrazoline derivative, a pyrazolone derivative, and a phthalocyanine derivative.

Specific but non-limiting examples of the dopant material of the light-emitting layer 24 may include a pyrene derivative, a fluoranthene derivative, an arylacetylene derivative, a fluorene derivative, a perylene derivative, an oxadiazole derivative, an anthracene derivative, and a chrysene derivative. Alternatively, the dopant material of the light-emitting layer 24 may include a metal complex. The metal complex may include a ligand and a metal atom of iridium (Ir), platinum (Pt), osmium (Os), gold (Au), rhenium (Re), or ruthenium (Ru), for example.

The electron transport layer 25 may transport electrons injected from the cathode 27 to the light-emitting layer 24. The electron transport layer 25 may mainly, but not necessarily mainly include an organic material having an electron transporting property (hereinafter referred to as “electron transporting material 25M”). The electron transport layer 25 may be a deposited film or a sputtered film. For example, the electron transport layer 25 may have a charge blocking property of suppressing or preventing tunneling of charges (e.g., holes in this example embodiment) from the light-emitting layer 24 to the cathode 27, and a property of suppressing or preventing light extinction of the light-emitting layer 24 in an excitation state.

The electron transporting material 25M of the electron transport layer 25 may include an aromatic heterocyclic compound containing one or more hetero atoms in a molecule, for example. The aromatic heterocyclic compound may contain, as a skeleton, a pyridine ring, a pyrimidine ring, a triazine ring, a benzimidazole ring, a phenanthroline ring, or a quinazoline ring, for example. Optionally, the electron transport layer 25 may contain a metal having an electron transporting property. The electron transport layer 25 that contains the metal having the electron transporting property exhibits an enhanced electron transporting property. Specific but non-limiting examples of the metal in the electron transport layer 25 may include barium (Ba), lithium (Li), calcium (Ca), potassium (K), cesium (Cs), sodium (Na), rubidium (Rb), and ytterbium (Yb).

The electron injection layer 26 may inject, in the electron transport layer 25 and the light-emitting layer 24, electrons injected from the cathode 27. The electron injection layer 26 may include, for example, an electron injecting material that facilitates the injection of electrons from the cathode 27 to the electron transport layer 25 and the light-emitting layer 24. The electron injecting material may include an organic material that has an electron injecting property and is doped with a metal having the electron injecting property, for example. The metal doped in the electron injection layer 26 may be the same as the metal doped in the electron transport layer 25, for example. The electron transport layer 25 may be, for example, a deposited film or a sputtered film.

In an example embodiment of the disclosure, one or more of the layers, such as the hole injection layer 22, the hole transport layer 23, and the light-emitting layer 24, in the organic electroluminescent element 12-2 may be shared between the subpixels 12 in the region (i.e., the groove 15) surrounded by two of the column regulators 14C that are adjacent to each other. In other words, one or more of the layers, such as the hole injection layer 22, the hole transport layer 23, and the light-emitting layer 24, in the organic electroluminescent element 12-2 may extend in the groove 15 along the column direction and beyond the row regulators 14D, so as to continuously extend over the subpixels 12 in the groove 15, as illustrated in FIGS. 3 to 6.

In another example embodiment of the disclosure, one or more of the layers, such as the hole injection layer 22, the hole transport layer 23, and the light-emitting layer 24, in the organic electroluminescent element 12-2 may not be shared between the subpixels 12 in each pixel 11, and may be individually provided for each of the subpixels 12 in each pixel 11. In other words, one or more of the layers, such as the hole injection layer 22, the hole transport layer 23, and the light-emitting layer 24, in the organic electroluminescent element 12-2 may be formed in a region not including the column regulators 14C, as illustrated in FIG. 4, for example. In still another embodiment of the disclosure, one or more of the layers, such as the electron transport layer 25 and the electron injection layer 26, in the organic electroluminescent element 12-2 may be shared between the subpixels 12 in each pixel 11. In other words, one or more of the layers, such as the electron transport layer 25 and the electron injection layer 26, in the organic electroluminescent element 12-2 may extend beyond the column regulators 14C, as illustrated in FIG. 4, for example.

In the example embodiment of the disclosure, the cathode 27 may extend over the entire pixel region of the organic electroluminescent panel 10. For example, the cathode 27 may continuously extend over the entire surfaces of the electron injection layer 26, the column regulators 14C, the row regulators 14D, and the line banks 13.

With reference to FIGS. 4 to 6, for example, the organic electroluminescent element 12-2 further includes a protection layer 28A that protects the organic electroluminescent element 12-2, and a sealing layer 28B that seals the organic electroluminescent element 12-2. The protection layer 28A may correspond to a specific but non-limiting example of “first refractive index layer” according to one embodiment of the disclosure. The sealing layer 28B may correspond to a specific but non-limiting example of “second refractive index layer” according to one embodiment of the disclosure.

The protection layer 28A and the sealing layer 28B may extend over the entire pixel region of the organic electroluminescent panel 10. For example, the protection layer 28A and the sealing layer 28B may be provided on the cathode 27. The protection layer 28A may be in contact with an upper surface of the cathode 27, for example. The sealing layer 28B may be in contact with an upper surface of the protection layer 28A, for example. The protection layer 28A and the sealing layer 28B are in contact with each other at an interface 28S. In each of the subpixels 12, the interface 28S has one or more recesses 28S1 that are opposed to the respective light-emitting regions 24A. In each of the subpixels 12, the protection layer 28A and the sealing layer 28B may be shared between the plurality of recesses 28S1. Note that the light-emitting region 24A may be provided on the light-emitting layer 24 at a position opposed to the bottom of the opening 14A. The recesses 28S1 may conform to the surfaces of the crosspieces 14B, the column regulators 14C, and the row regulators 14D. The recesses 28S1 may each have a bulging side face that protrudes in a direction remote from the substrate 16. The recess 28S1 may be formed by forming an inorganic material film on the surface of the cathode 27 by sputtering or chemical vapor deposition (CVD). Such a recess 28S1 may have a shape conforming to the surface of the cathode 27 and the surface of the insulating layer 14 that includes the column regulators 14C, the row regulators 14D, and the crosspieces 14B. An upper surface of the sealing layer 28B, which is remote from the protection layer 28A, may be a flat surface parallel to a surface of the substrate 16, for example.

The protection layer 28A may have a refractive index less than that of the sealing layer 28B. The refractive index of the protection layer 28A may be about 1.68, and the refractive index of the sealing layer 28B may be about 1.75, for example. The protection layer 28A may include an inorganic material, and the sealing layer 28B may include a resin material. Specific but non-limiting examples of the inorganic material of the protection layer 28A may include SiN, SiON, and SiO2. Specific but non-limiting examples of the resin material of the sealing layer 28B may include epoxy resin and vinyl resin. The recess 28S1 may serve as a convex lens for light emitted from the light-emitting region 24A. In other words, the recess 28S1 may have a lens effect.

In one example, the recess 28S1 may have a bottom positioned below the upper surfaces of the crosspieces 14B, the column regulators 14C, and the row regulators 14D. The recess 28S1 having such a shape serves as a convex lens having an improved light condensing property.

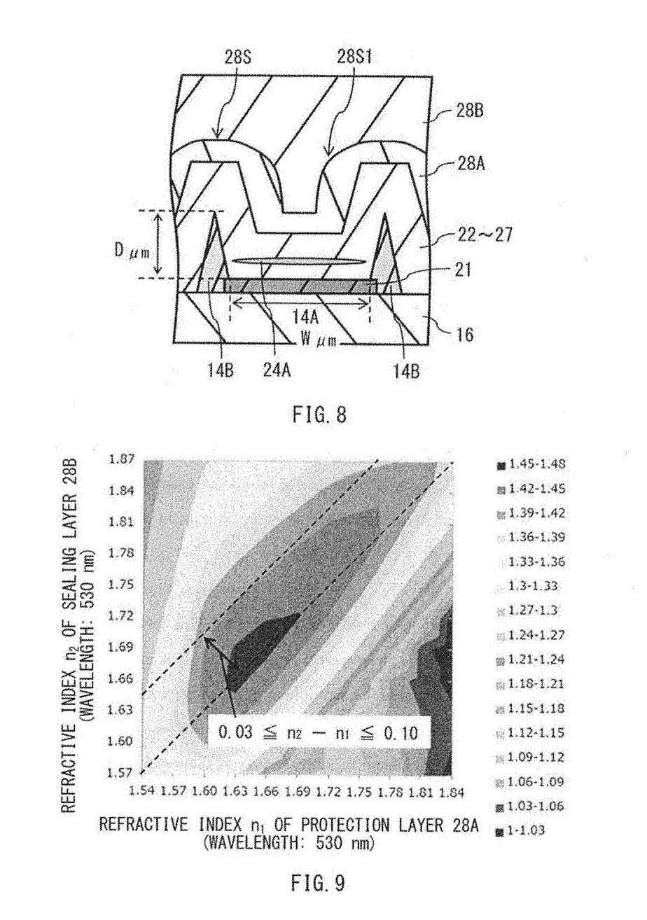

An aspect ratio of the opening 14A that defines the shape of the recess 28S1 will now be described. With reference to FIG. 8, for example, the aspect ratio of the opening 14A may be represented by D/W, where W denotes the width of the bottom of the opening 14A, D denotes the distance between a top portion of the insulating layer 14 and the bottom of the opening 14A. The bottom of the opening 14A may correspond to a surface of the anode 21 exposed in the opening 14A.

FIG. 9 illustrates an example relation of the respective refractive indices n1 and n2 of the protection layer 28A and the sealing layer 28B versus a magnification of light emission efficiency obtained by the recess 28S1 having the lens effect relative to light emission efficiency obtained in a case having no lens effect. The magnification of light emission efficiency may be hereinafter referred to as “luminance magnification”. FIG. 9 illustrates the result of a simulation where the bottom of the opening 14A had a width W of 5 μm, the protection layer 28A had a thickness of 5 μm, the opening 14A had an aspect ratio of 1.2, and the insulating layer 14 had a refractive index of 1.55 in a wavelength of 530 nm. As illustrated in FIG. 9, the luminance magnification became high when a refractive index difference Δn between the refractive index n1 of the protection layer 28A and the refractive index n2 of the sealing layer 28B (i.e., n2−n1) was within a range from 0.03 to 0.10.

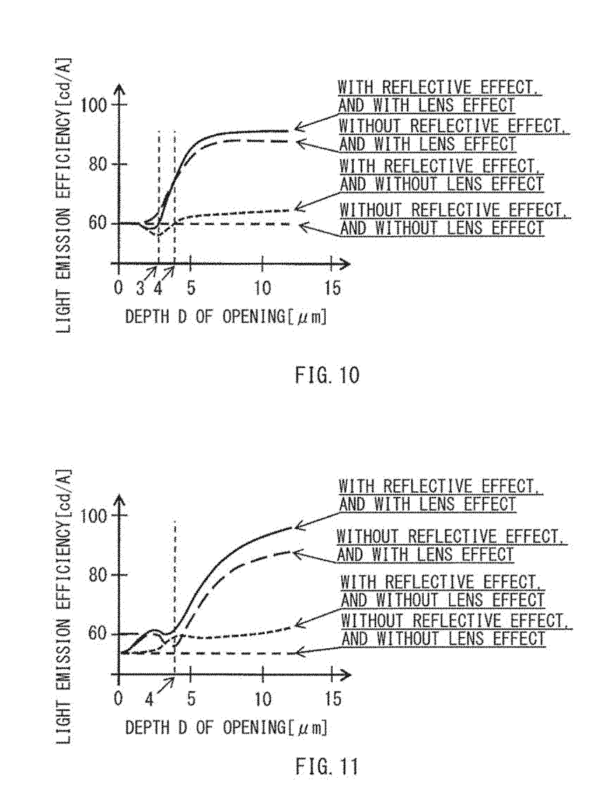

FIG. 10 illustrates an example relation between a depth D of the opening 14A (i.e., depth of the recess 28S1) and light emission efficiency. FIG. 10 illustrates the result of a simulation where the bottom of the opening 14A had a width W of 5 μm, the insulating layer 14 had a refractive index of 1.55 in a wavelength of 530 nm, the protection layer 28A had a refractive index of 1.68 in a wavelength of 530 nm, and the sealing layer 28B had a refractive index of 1.72 in a wavelength of 530 nm.

It is apparent from FIG. 10 that the depth D of the opening 14A (i.e., the depth of the recess 28S1) may be 3 μm or greater to improve the lens effect or front luminance. In this case, the opening 14A may have an aspect ratio of 0.6 (3 μm/5 μm) or greater. It is also apparent from FIG. 10 that the depth D of the opening 14A (i.e., the depth of the recess 28S1) may be 4 μm or greater to improve the light emission efficiency or reflection effect. In this case, the opening 14A may have an aspect ratio of 0.8 (4 μm /5 μm) or greater.

FIG. 11 illustrates an example relation between the depth D of the opening 14A (i.e., the depth of the recess 28S1) and the light emission efficiency. FIG. 11 illustrates the result of the light-emitting layer 24 having film-thickness distribution. Note that, in the light-emitting layer 24 having the film-thickness distribution, a portion having a thickness different at the 10% level or less from the thickness of the center of the light-emitting region 24A may have an effective width that is 40% of the width W of the bottom of the opening 14A. FIG. 11 illustrates the result of a simulation where the bottom of the opening 14A had a width W of 5 μm, the insulating layer 14 had a refractive index of 1.55 in a wavelength of 530 nm, the protection layer 28A had a refractive index of 1.68 in a wavelength of 530 nm, and the sealing layer 28B had a refractive index 1.72 in a wavelength of 530 nm.

It is apparent from FIG. 11, for example, that the depth D of the opening 14A (i.e., the depth of the recess 28S1) may be 4 μm or greater to improve the front luminance or lens effect. In this case, the opening 14A may have an aspect ratio of 0.8 (4 μm/5 μm) or greater. It is also apparent from FIG. 11 that the depth D of the opening 14A (the depth of the recess 28S1) may be 4 μm or greater to improve the light emission efficiency or the reflection effect. In this case, the opening 14A may have an aspect ratio of 0.8 (4 μm/5 μm) or greater.

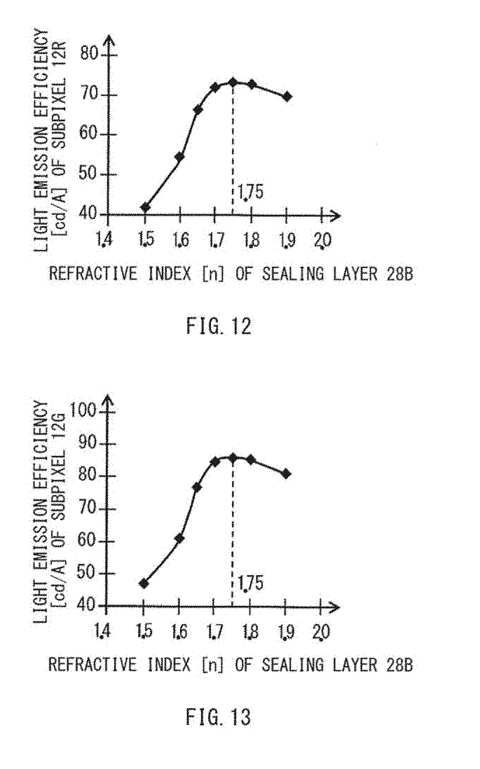

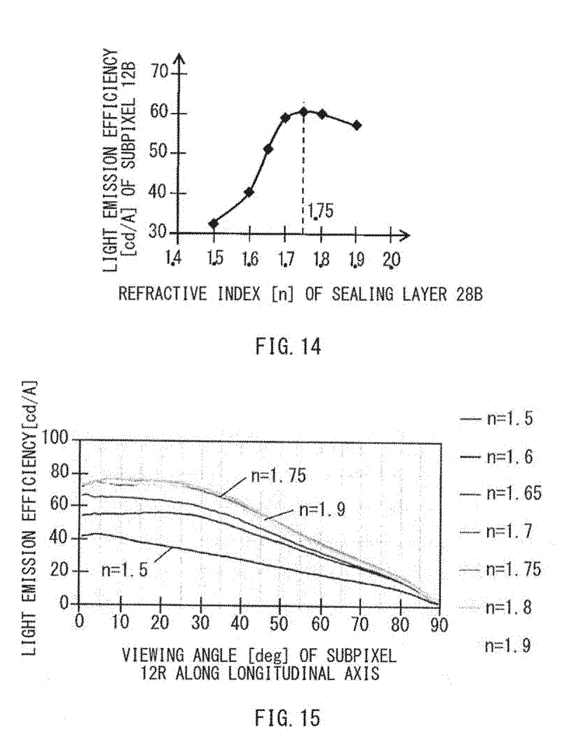

FIGS. 12 to 14 illustrate an example relation between the refractive index of the sealing layer 28B and light emission efficiency. FIG. 12 illustrates an example relation between the refractive index of the sealing layer 28B and light emission efficiency of the red subpixel 12R. FIG. 13 illustrates an example relation between the refractive index of the sealing layer 28B and light emission efficiency of the green subpixel 12G. FIG. 14 illustrates an example relation between the refractive index of the sealing layer 28B and light emission efficiency of the blue subpixel 12B.

As illustrated in FIGS. 12 to 14, the light emission efficiency of each of the subpixels 12R, 12G, and 12B is maximum when the refractive index of the sealing layer 28B is around 1.75. Additionally, the light emission efficiency of each of the subpixels 12R, 12G, and 12B sharply decreases when the refractive index of the sealing layer 28B is less than 1.7. It is apparent from the FIGS. 12 to 14 that there is no significant difference between the subpixels 12R, 12G, and 12B in terms of a change in light emission efficiency, and thus the light emission efficiency is less dependent on the color of the subpixel.

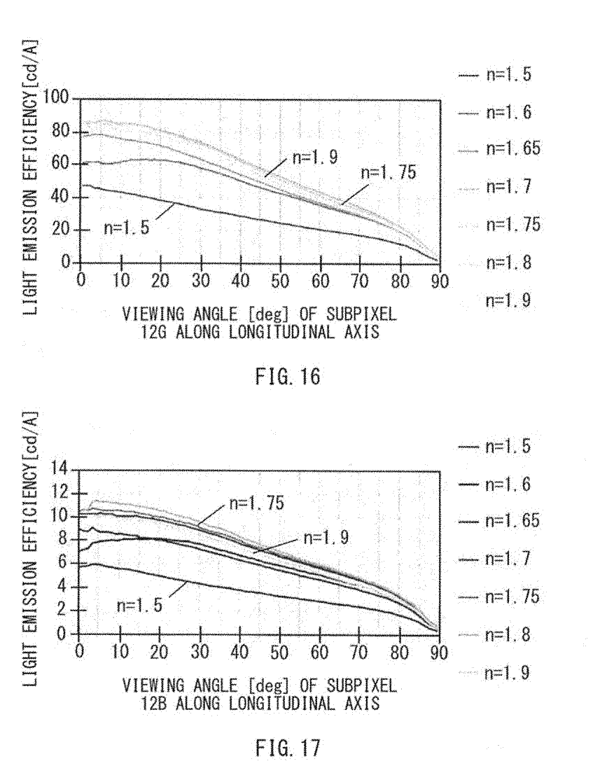

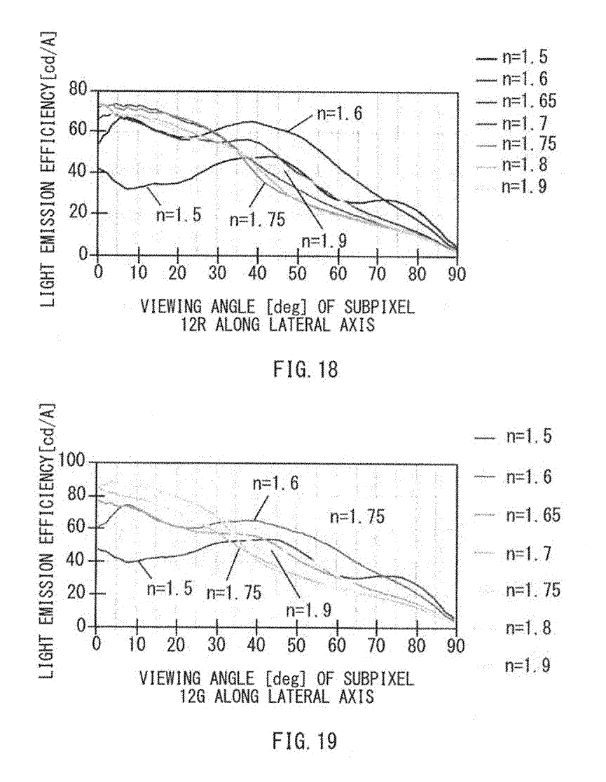

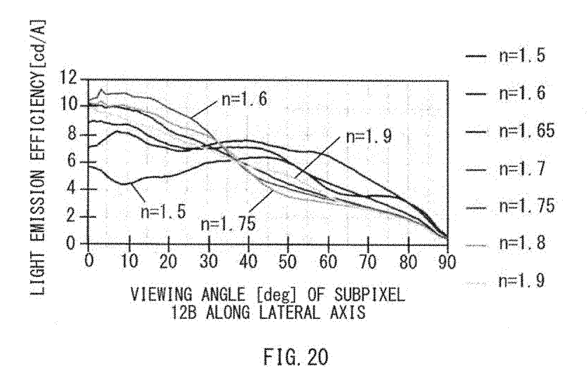

FIGS. 15 to 20 each illustrate an example viewing angle characteristic of the subpixel 12. FIG. 15 illustrates an example viewing angle characteristic along a longitudinal direction of the red subpixel 12R. FIG. 16 illustrates an example viewing angle characteristic along the longitudinal direction of the green subpixel 12G. FIG. 17 illustrates an example viewing angle characteristic along the longitudinal direction of the blue subpixel 12B. FIG. 18 illustrate an example viewing angle characteristic along a lateral direction of the red subpixel 12R. FIG. 19 illustrates an example viewing angle characteristic along the lateral direction of the green subpixel 12G. FIG. 20 illustrates an example viewing angle characteristic along the lateral direction of the blue subpixel 12B.

As illustrated in FIGS. 15 to 17, the light emission efficiencies along the longitudinal direction of the subpixels 12R, 12G, and 12B are all increased thanks to the lens effect at a peak where the refractive index of the sealing layer 28B is around 1.75. It is apparent from FIGS. 15 to 17 that there is no significant difference between the subpixels 12R, 12G, and 12B in terms of a change in light emission efficiency along the longitudinal axis, and thus the light emission efficiency is less dependent on the color of the subpixel. As illustrated in FIGS. 18 to 20, when the refractive index of the sealing layer 28B is 1.75 or greater, the front luminance along the lateral direction is increased by the lens effect, and light emission efficiency along an oblique direction is reduced. On the other hand, as illustrated in FIGS. 18 to 20, when the refractive index is less than 1.75, the refractive index of the sealing layer 28B along the lateral direction is reduced, and the light emission efficiency along an oblique direction is increased.

### Example Effects

Described below are some example effects of the organic electroluminescent panel 10 according to the example embodiment of the disclosure and the organic electroluminescent unit 1 that includes the organic electroluminescent panel 10.

In any example embodiment of the disclosure, the interface 28S between the protection layer 28A and the sealing layer 28B that are provided on the cathode 27 may have the recess 28S1 opposed to the light-emitting region 24A. This allows light emitted obliquely from the light-emitting region 24A to be raised in a frontal direction. Accordingly, it is possible to improve the front luminance.

In an example embodiment of the disclosure, the refractive index of the protection layer 28A may be less than that of the sealing layer 28B. This allows light emitted obliquely from the light-emitting region 24A to be raised in a frontal direction. Accordingly, it is possible to improve the front luminance.

In an example embodiment of the disclosure in which the protection layer 28A may include an inorganic material, and the sealing layer 28B may include a resin material, the protection layer 28A may be formed by sputtering or CVD into a shape conforming to a layer underlying the recess 28S1, and the recess 28S1 may be filled with the sealing layer 28B having a flat upper surface. This allows the front luminance to be relatively readily controlled during the manufacturing process.

In an example embodiment of the disclosure, the column regulators 14C, the row regulators 14D, and the crosspieces 14B may be provided on the substrate 16 and around the light-emitting regions 24A. The upper surfaces of the column regulators 14C, the row regulators 14D, and the crosspieces 14B may be positioned above the light-emitting regions 24A. The recess 28S1 may have a shape conforming to the surfaces of the column regulators 14C, the row regulators 14D, and the crosspieces 14B. The recess 28S1 may thus be formed by forming the protection layer 28A over the entire surface including the column regulators 14C, the row regulators 14D, and the crosspieces 14B, by sputtering, for example. This allows the front luminance to be relatively readily controlled during the manufacturing process.

In an example embodiment of the disclosure, the recess 28S1 may have the bottom positioned below the upper surfaces of the column regulators 14C and the crosspieces 14B. This allows light emitted obliquely from the light-emitting region 24A to be raised in a more frontal direction. Accordingly, it is possible to improve the front luminance.

In an example embodiment of the disclosure, the recess 28S1 may have the bulge on its side face. The bulge protrudes in the direction remote from the substrate 16. This allows light emitted obliquely from the light-emitting region 24A to be raised in a more frontal direction. Accordingly, it is possible to improve the front luminance.

In an example embodiment of the disclosure, the aspect ratio of the opening 14A may be 0.8 or greater, and the shape of the recess 28S1 may conform to the opening 14A. This allows light emitted obliquely from the light-emitting region 24A to be raised in a more frontal direction. Accordingly, it is possible to improve the front luminance.

In an example embodiment of the disclosure, the column regulators 14C, the row regulators 14D, and the crosspieces 14B may each have the reflective side face that reflects light emitted obliquely from the light-emitting region 24A toward a normal direction of the substrate 16. This allows light emitted obliquely from the light-emitting region 24A to be reflected from the reflective surface and raised in a more frontal direction. Accordingly, it is possible to improve the front luminance.

In each of the subpixels 12 according to an example embodiment of the disclosure, the interface 28S may have the plurality of recesses 28S1, and the protection layer 28A and the sealing layer 28B may be shared between the plurality of recesses 28S1. Accordingly, it is possible to improve the front luminance by a simple manufacturing method. Furthermore, it is possible to improve the front luminance by increasing the number of the recesses 28S1 configured to raise light.

In each of the subpixels 12 according to an example embodiment of the disclosure, the light-emitting layer 24 may have the plurality of light-emitting regions 24A each having a strip shape, and the crosspieces 14B may be disposed between two of the light-emitting regions 24A that are adjacent to each other. This allows light emitted obliquely from the light-emitting region 24A and traveling in a direction crossing the extending direction of the crosspieces 14B to be raised in a more frontal direction. Accordingly, it is possible to improve the front luminance.

In each of the subpixels 12 according to an example embodiment of the disclosure, the light-emitting layer 24 may include the light-emitting regions 24A each having an island shape, and the light-emitting regions 24A may be surrounded by the column regulators 14C, the row regulators 14D, and the crosspieces 14B. This allows light emitted obliquely from the light-emitting region 24A to be raised in a more frontal direction. Accordingly, it is possible to improve the front luminance.

### 2. MODIFICATION EXAMPLE

Some modification examples of the organic electroluminescent unit 1 according to the foregoing example embodiment will now be described.

### Modification Example A

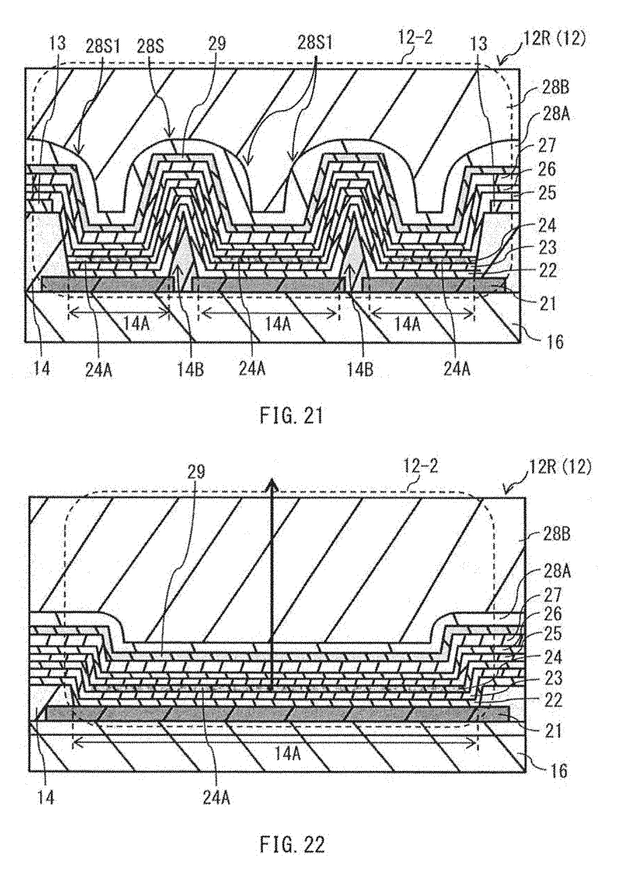

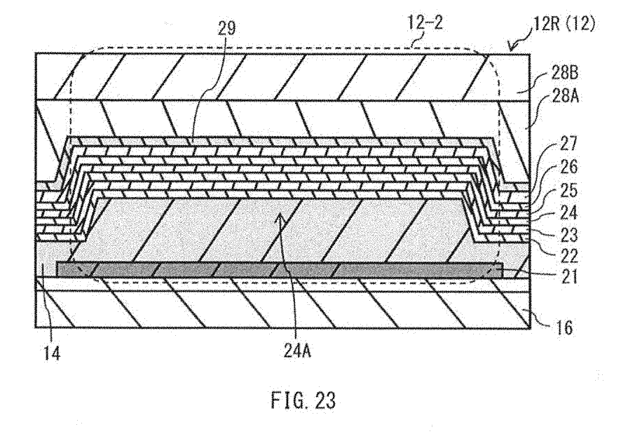

FIG. 21 illustrates Modification Example A of a cross-sectional configuration of the organic electroluminescent panel 10 taken along the line A-A in FIG. 3. FIG. 22 illustrates Modification Example A of a cross-sectional configuration of the organic electroluminescent panel 10 taken along the line B-B in FIG. 3. FIG. 23 illustrates Modification Example A of a cross-sectional configuration of the organic electroluminescent panel 10 taken along the line C-C in FIG. 3. FIGS. 21 to 23 each illustrate the organic electroluminescent panel 10 that includes a light-distribution control layer 29.

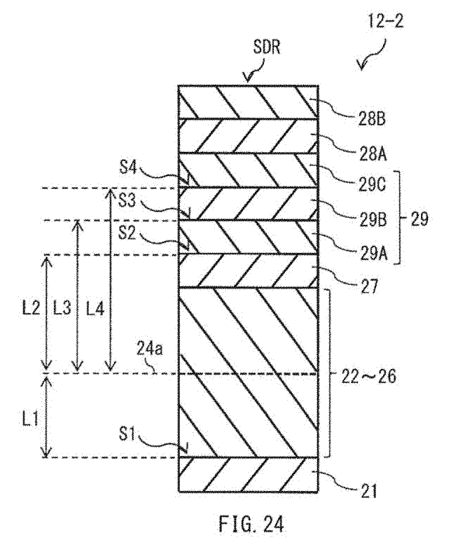

According to Modification Example A, the organic electroluminescent panel 10 may include the light-distribution control layer 29 between the cathode 27 and the protection layer 28A. The light-distribution control layer 29 may be in contact with the upper surface of the cathode 27. With reference to FIG. 24, for example, the light-distribution control layer 29 may be a multi-layer film that includes light transmission layers 29A, 29B, and 29C that are stacked in this order from the cathode 27. The light transmission layers 29A, 29B, and 29C may include, for example, a transparent electrically-conductive material or a transparent dielectric material.

Specific but non-limiting examples of the transparent electrically-conductive material of the light transmission layers 29A, 29B, and 29C may include ITO and IZO. Specific but non-limiting examples of the transparent dielectric material of the light transmission layers 29A, 29B, and 29C may include silicon oxide (e.g., SiO2), silicon oxide nitride (e.g., SiON), and silicon nitride (e.g., SiN). The light transmission layers 29A, 29B, and 29C may also serve as the cathode 27, or may also serve as passivation films. The light transmission layers 29A, 29B, and 29C may each include a material having a low refractive index, such as MgF or NaF.

The anode 21 and the light transmission layers 29A, 29B, and 29C may together serve as a resonating structure. In Modification Example A, the protection layer 28A and the sealing layer 28B may prevent external interference to be imposed on the resonating structure that includes the anode 21 and the light transmission layers 29A, 29B, and 29C, as well as serving as a condenser lens.

A reflective surface S1 may be formed on an upper surface of the anode 21 by a refractive index difference between the anode 21 and a layer in contact with the upper surface of the anode 21 (i.e., the hole injection layer 22 or the hole transport layer 23). The reflective surface S1 may be provided at a position remote from a luminescent center 24a of the light-emitting layer 24 by an optical path length L1. The optical path length L1 may be determined so that light from the light-emitting layer 24 having an emission spectrum with a central wavelength λ1 is amplified by interference between the reflective surface S1 and the luminescent center 24a. For example, the optical path length L1 may be determined to satisfy the following Expressions 5 and 6:

(2L1/λ11)+(a1/2π)=m1 Expression 5

λ1−150<λ11<λ1+80 Expression 6

where a1 denotes a phase variation upon reflection, from the reflective surface S1, of light emitted from the light-emitting layer 24, λ11 denotes a wavelength satisfying Expression 6, and m1 denotes an integer equal to or greater than zero. Note that the unit of the L1, λ1, and λ11 is nanometer (nm) in Expressions 5 and 6.

The anode 21 may have a complex refractive index N that is represented by n0−jk, where n0 denotes a refractive index, and k denotes an extinction coefficient. The phase variation a1 may be calculated using the refractive index n0, the extinction coefficient k, and the refractive index of the light-emitting layer 24. Reference is made to “Principles of Optics, Max Born and Emil Wolf, 1974 (PERGAMON PRESS)”, for example. The complex refractive index N of the anode 21 and the refractive index of the light-emitting layer 24 may be measured using a spectral ellipsometer, for example.

The value of m1 may be zero, for example. One reason for this is that a so-called microcavity effect may not be obtained in a case where the value of m1 is large. In Expression 6 described above, λ1 may be equal to 600 nm. For example, the optical path length L1 may satisfy the following Expressions 7 and 8.

(2L1/λ11)+(a1/2π)=0 Expression 7

λ1−150=450<λ11=600<λ1+80=680 Expression 8

The reflective surface S1 satisfying Expression 7 may be disposed at a zero-order interference position. Therefore, the reflective surface S1 has a high transmittance over a wide wavelength band. This allows the wavelength λ11 to be largely shifted from the central wavelength λ1, as in Expression 8.

A reflective surface S2 may be formed on the upper surface of the cathode 27 by a refractive index difference between the cathode 27 and a layer in contact with the upper surface of the cathode 27 (i.e., the light transmission layer 29A). The reflective surface S2 may be provided at a position remote from the luminescent center 24a of the light-emitting layer 24 by an optical path length L2. The optical path length L2 may be determined so that light from the light-emitting layer 24 having the emission spectrum with the central wavelength λ1 is amplified by interference between the reflective surface S2 and the luminescent center 24a. For example, the optical path length L2 may be determined to satisfy the following Expressions 9 and 10:

(2L2/λ12)+(a2/2π)=m2 Expression 9

λ1−80<λ12<λ1+80 Expression 10

where a2 denotes a phase variation upon reflection, from the reflective surface S2, of light emitted from the light-emitting layer 24, λ12 denotes a wavelength satisfying Expression 10, and m2 denotes an integer equal to or greater than zero. Note that the unit of the L2, λ1, and λ12 is nanometer (nm) in Expressions 9 and 10.

The light transmission layer 29A may have a complex refractive index N that is represented by n0−jk, where n0 denotes a refractive index, and k denotes an extinction coefficient. The phase variation a2 may be calculated using the refractive index n0, the extinction coefficient k, and the refractive index of the light-emitting layer 24. The complex refractive index N of the light transmission layer 29A and the refractive index of the light-emitting layer 24 may be measured using a spectral ellipsometer, for example.

The value of m2 may thus be 1, for example. One reason for this is that a so-called microcavity effect may be not obtained in a case where the value of m2 is large.

Light emitted from the light-emitting layer 24 may be amplified between the reflective surface S1 and the luminescent center 24a and between the reflective surface S2 and the luminescent center 24a. This amplifying effect causes the light transmittance to exhibit a peak around 620 nm.

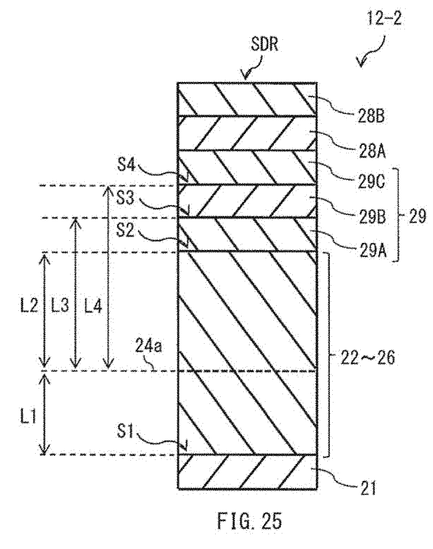

In another embodiment of the disclosure illustrated in FIG. 25, for example, the cathode 27 may not be provided, and the light transmission layer 29A may also serve as the cathode 27. Additionally, the reflective surface S2 may be formed by a refractive index difference between the electron transport layer 25 and the light transmission layer 29A or a refractive index difference between the electron injection layer 26 and the light transmission layer 29A.

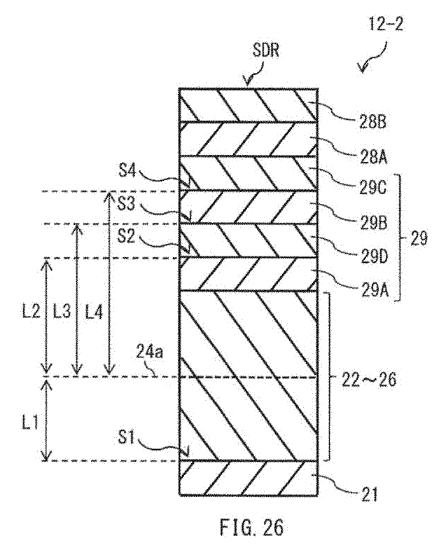

In still another embodiment of the disclosure illustrated in FIG. 26, for example, a light transmission layer 29D may be provided between the light transmission layer 29A and a light transmission layer 29B, and the reflective surface S2 may be formed by a refractive index difference between the light transmission layer 29D and the light transmission layer 29A.

A reflective surface S3 may be formed on an upper surface of the light transmission layer 29A by a refractive index difference between the light transmission layer 29A and a layer in contact with the upper surface of the light transmission layer 29A (i.e., the light transmission layer 29B). The reflective surface S3 may be provided at a position remote from the luminescent center 24a of the light-emitting layer by an optical path length L3. In the red subpixel 12R, the optical path length L3 may be determined so that light from the light-emitting layer 24 having an emission spectrum with a central wavelength λ1R is attenuated by interference between the reflective surface S3 and the luminescent center 24a. In the blue subpixel 12B, the optical path length L3 may be determined so that light from the light-emitting layer 24 having an emission spectrum with a central wavelength λ1B is amplified by interference between the reflective surface S3 and the luminescent center 24a. For example, in the red subpixel 12R, the optical path length L3 may be determined to satisfy the following Expressions 11 and 12:

(2L3/λ13)+(a3/2π)=m3+½ Expression 11

λ1R−150<λ13<λ1R+150 Expression 12

where a3 denotes a phase variation upon reflection, from the reflective surface S3, of light emitted from the light-emitting layer 24, λ13 denotes a wavelength satisfying Expression 12, and m3 denotes an integer equal to or greater than zero. Additionally, in the blue subpixel 12B, the optical path length L3 may be determined to satisfy the following Expressions 13 and 14:

(2L3/λ23)+(a3/2π)=n3 Expression 13

λ1B−150<λ23<λ1B+150 Expression 14

where λ23 denotes a wavelength satisfying Expression 14, and n3 denotes an integer equal to or greater than zero. Note that the unit of L3, λ1, and λ13 is nanometer (nm) in Expressions 11 to 14.

A reflective surface S4 may be formed on an upper surface of the light transmission layer 29B by a refractive index difference between the light transmission layer 29B and a layer in contact with the upper surface of the light transmission layer 29B (i.e., the light transmission layer 29C). The reflective surface S4 may be provided at a position remote from the luminescent center 24a of the light-emitting layer 24 by an optical path length L4. In the red subpixel 12R, the optical path length L4 may be determined so that light from the light-emitting layer 24 having the emission spectrum with the central wavelength λ1R is attenuated by interference between the reflective surface S4 and the luminescent center 24a. In the blue subpixel 12B, the optical path length L4 may be determined so that light from the light-emitting layer 24 having the emission spectrum with the central wavelength λ1B is amplified by interference between the reflective surface S4 and the luminescent center 24a. For example, in the red subpixel 12R, the optical path length L4 may be determined to satisfy the following Expressions 15 and 16:

(2L4/λ14)+(a4/2π)=m4+½ Expression 15

λ1R−150<λ14<λ1R+150 Expression 16

where a4 denotes a phase variation upon reflection, from the reflective surface S4, of light emitted from the light-emitting layer 24, λ14 denotes a wavelength satisfying Expression 15, and m4 denotes an integer equal to or greater than zero. Additionally, in the blue subpixel 12B, the optical path length L4 may be determined to satisfy the following Expressions 17 and 18:

(2L4/λ24)+(a3/2π)=n4 Expression 17

λ1B−150<λ24<λ1B+150 Expression 18

where λ24 denotes a wavelength satisfying Expression 17, and n4 denotes an integer equal to or greater than zero. Note that the unit of L4, λ1 , and λ14 is nanometer (nm) in Expressions 15 to 18.

The light transmission layer 29B may have a complex refractive index N that is represented by n0−jk, where n0 denotes a refractive index, and k denotes an extinction coefficient. The phase variation a3 may be calculated using the refractive index n0, the extinction coefficient k, and the refractive index of the light-emitting layer 24. The light transmission layer 29C may have a complex refractive index N that is represented by n0−jk, where n0 denotes a refractive index, and k denotes an extinction coefficient. The phase variation a4 may be determined using the refractive index n0, the extinction coefficient k, and the refractive index of the light-emitting layer 24. The complex refractive indices N of the light transmission layers 29B and 29C and the refractive index of the light-emitting layer 24 may be measured using a spectral ellipsometer, for example.

As described above, conditions of the reflection from the reflective surfaces S3 and S4 may be different between the red subpixel 12R and the blue subpixel 12B. This allows for an individual adjustment of a luminance state in each of the subpixels 12, which is described in detail below.

In the foregoing example embodiment, light generated from the red light-emitting layer 24 may be attenuated by the reflection from the reflective surface S3, and a half width of the spectrum is thereby increased. Additionally, light generated from the red light-emitting layer 24 may be further attenuated by the reflection from the reflective surface S4, and the half width of the spectrum is thereby further increased. Accordingly, the peak region of the spectrum may be smoothed, which suppresses an abrupt change in the luminance and hue depending on angles. Light generated from the blue light-emitting layer 24 may be amplified by the reflection from the reflective surface S4, and the peak value is thereby increased. Causing such a sharp peak leads to higher light extraction efficiency and an improved chromaticity point. In one example, the position of the peak of the spectrum generated on the reflective surfaces S1 and S2 may be aligned with the position of the peak of the spectrum generated on the reflective surfaces S3 and S4. In another example, the position of the peak of the spectrum generated on the reflective surfaces S1 and S2 may be shifted from the position of the peak of the spectrum generated on the reflective surfaces S3 and S4. Shifting the position of the peak of the spectrum generated on the reflective surfaces S1 and S2 from the position of the peak of the spectrum generated on the reflective surfaces S3 and S4 helps to enlarge a wavelength band in which the resonating structure works effectively, and suppress an abrupt change in luminance and hue.

Described below are some example workings and effects of the organic electroluminescent unit 1 according to Modification Example A.

In Modification Example A, light emitted from the light-emitting layer 24 may be reflected multiple times between the reflective surface S1 and the reflective surface S4, and thereafter extracted from a light extraction surface SDR. Meanwhile, it is difficult to improve a light distribution characteristic in a general organic electroluminescent unit.

International Publication No. WO 2001/039554, for example, discloses a method of enhancing light emission efficiency. The method involves determining the thickness of a film between a light-transmissive electrode and a reflective electrode so that light having a desired wavelength resonates. Additionally, Japanese Unexamined Patent Application Publication No. 2011-159433, for example, discloses an attempt to improve a viewing angle characteristic at a white chromaticity point. This attempt involves controlling an attenuation balance between three primary colors (i.e., red, green, and blue) by controlling the thickness of an organic layer.

However, in these technologies described above, the laminate structure of an organic electroluminescent element serves as an interference filter causing extracted light to have a narrow half width of a spectrum. This causes a large shift in wavelength of light when the light extraction surface is seen in an oblique direction. Accordingly, a light intensity can be reduced depending on viewing angles. In other words, the light intensity is highly dependent on viewing angles.

Japanese Unexamined Patent Application Publication No. 2006-244713, for example, discloses a structure for reducing a hue change dependent on viewing angles. The structure can be effective to reduce the viewing angle dependency of luminance of a monochrome device; however, it is difficult to apply the structure to a device that requires a sufficiently large wavelength band. One conceivable measure to enlarge an applicable wavelength band is to increase a reflection rate. The measure, however, can result in a significant decrease in light extraction efficiency.

As described above, one conceivable measure to reduce the angular dependency is to adjust positional relations and emission positions in the laminated structure of the organic electroluminescent element. However, such an adjustment is sometimes difficult to be achieved, for example, in a case where wavelength dispersions of refractive indices are caused by the spectra of light emitted from the respective light-emitting layers. In the wavelength dispersions of refractive indices, a refractive index of the constituent material differs depending on wavelength. Therefore, effects of the resonating structure are different between the red organic electroluminescent element, the green organic electroluminescent element, and the blue organic electroluminescent element. For example, the peak of the red light extracted from the red organic electroluminescent element becomes too sharp, whereas the peak of the blue light extracted from the blue organic electroluminescent element becomes too moderate. Such a significant difference in the effect of the resonating structure between the device regions can increase the angular dependency of luminance and hue, resulting in a decrease in the light distribution characteristic.

In contrast, according to Modification Example A of the disclosure, the effect that the reflective surfaces S3 and S4 impose on light generated from the red light-emitting layer 24 may be different from the effect that the reflective surfaces S3 and S4 impose on light generated from the blue light-emitting layer 24. The effects imposed on the light generated from the red light-emitting layer 24 and the light generated from the blue light-emitting layer 24 are as follows.

The light generated from the red light-emitting layer 24 may be attenuated by interference between the luminescent center 24a of the red light-emitting layer 24 and the reflective surface S3 of the red subpixel 12R and between the luminescent center 24a of the red light-emitting layer 24 and the reflective surface S4 of the red subpixel 12R. In contrast, the light generated from the blue light-emitting layer 24 may be amplified by interface between the luminescent center 24a of the blue light-emitting layer 24 and the refractive surface S3 of the blue subpixel 12B and between the luminescent center 24a of the blue light-emitting layer 24 and the reflective surface S4 of the blue subpixel 12B.

This allows red light extracted from the light extraction surface SDR to have a moderate peak in the red subpixel 12R, and allows blue light extracted from the light extraction surface SDB to have a sharp peak in the blue subpixel 12B. This reduces the difference in the effect of the resonating structure between the red subpixel 12R and the blue subpixel 12B, and thus reduces the angular dependency of the luminance and hue. This helps to improve the light distribution characteristic. The organic electroluminescent unit 1 having an improved light distribution characteristic may be suitable for a display unit that desirably display a high-grade image, and helps to improve the productivity of the display unit.

The organic electroluminescent unit 1 according to Modification Example A may maintain a chromaticity difference Δuv equal to or less than 0.015 and luminance of 60% or greater even at a 45° viewing angle. Therefore, the organic electroluminescent unit 1 makes it possible to achieve high-quality image displaying.

As described above, in the organic electroluminescent unit 1 according to Modification Example A, the reflective surfaces S3 and S4 of the red subpixel 12R may attenuate light generated from the red light-emitting layer 24, while the reflective surfaces S3 and S4 of the blue subpixel 12B may amplify light generated from the blue light-emitting layer 24. This allows for an individual adjustment of the effect of the resonating structure for each subpixel 12, improving the light distribution characteristic.

This also allows for high light transmittance over a large wavelength band. The light extraction efficiency is thereby enhanced, and power consumption is thereby reduced.

Note that each of the reflective surfaces S3 and S4 may be a laminate of metal thin-films each having a thickness of 5 nm or greater to achieve high light transmittance over a large wavelength band.

Additionally, the organic electroluminescent unit 1 according to Modification Example A may be suitable for a case in which the light-emitting layer 24 is a printed layer. Such a light-emitting layer 24 may be prone to cause regional variations in thickness after a drying process. In other words, the light-emitting layer 24 is likely to have a film-thickness distribution. In the organic electroluminescent unit 1 according to Modification Example A, the difference in the effect of the resonating structure between the subpixels 12 caused by the film-thickness distribution may be adjusted.

### Modification Example B

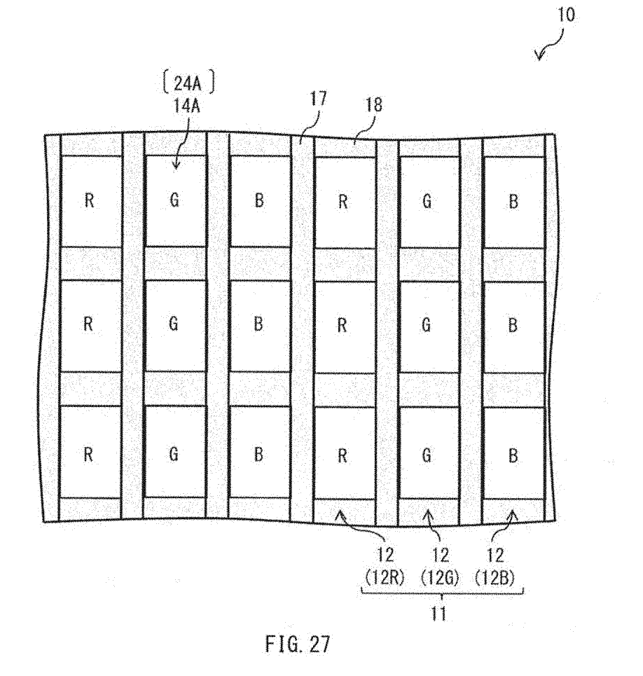

With reference to FIG. 27, for example, the organic electroluminescent panel 10 of the organic electroluminescent unit 1 according to the foregoing example embodiment and the modification example may include a plurality of line banks 17 and a plurality of banks 18, in place of the insulating layer 14, on the substrate 16. The line banks 17 may extend in the column direction, and the banks 18 may extend in the row direction. The line banks 17 and the banks 18 may correspond to a specific but non-limiting example of “pedestal” according to one embodiment of the disclosure. The line banks 17 and the banks 18 may define each of the subpixels 12. The line banks 17 may partition each of the pixels 11 into the subpixels 12. The banks 18 may partition each pixel row into the pixels 11. Each of the banks 18 may be disposed between two of the line banks 17 that are adjacent to each other. Opposite ends of the bank 18 may be respectively coupled to the two line banks 17 adjacent to each other. In other words, each of the subpixels 12 may be defined by two of the line banks 17 that are adjacent to each other and two of the banks 18 that are adjacent to each other.

The organic electroluminescent panel 10 may further include the opening 14A in a region surrounded by two of the line banks 17 that are adjacent to each other and two of the banks 18 that are adjacent to each other. In each of the subpixels 12, the surface of the anode 21 may be exposed at the bottom of the opening 14A. This allows holes supplied from the anode 21 exposed at the bottom of the opening 14A to be recombined with respective electrons supplied from the cathode 27 described below in the light-emitting layer 24, causing the light-emitting layer 24 to emit light. Accordingly, the light-emitting layer 24 may have the light-emitting regions 24A opposed to the respective openings 14A at the bottom of which the anode 21 is exposed.

The line banks 17 and the banks 18 may surround the light-emitting regions 24A, and may each have an upper surface positioned above the light-emitting regions 24A. In one example, the height of the bank 18 from the substrate 16 may be smaller than the height of the line bank 17 from the substrate 16. For example, the height of the bank 18 from the substrate 16 may be equal to or smaller than half the distance between the anode 21 and the cathode 27 in the organic electroluminescent element 12-2. In this example, the subpixels 12 arranged in the column direction may be provided in a strip groove 15 defined by two of the line banks 17 opposite to each other, and may share the light-emitting layer 24. In this example, the subpixels 12 arranged in the row direction may each provided in a strip groove 15 defined by two of the line banks 17 opposite to each other, and may share the light-emitting layer 24. In other words, the light-emitting layer 24 may extend beyond the bank 18 from one subpixel 12 to another subpixel 12 that are adjacent to each other. In other words, the light-emitting layer 24 may be shared between two of the subpixels 12 that are adjacent to each other across the bank 18.

The recess 28S1 may conform to the surfaces of the line bank 17 and the bank 18. The recess 28S1 may have a bulging side face that protrudes in a direction remote from the substrate 16. The recess 28S1 may be formed by forming an inorganic material film on the surface of the cathode 27 by sputtering, for example. Such a recess 28S1 may have a shape conforming to the surface of the cathode 27 and the surfaces of the line bank 17 and the bank 18. The upper surface, remoted from the protection layer 28A, of the sealing layer 28B may be a flat surface parallel to the surface of the substrate 16.

The line banks 17 and the banks 18 may include, for example, an insulating organic material. Specific but non-limiting examples of the insulating organic material may include acrylic resin, polyimide resin, and novolac phenol resin. In one example, the line banks 17 and the banks 18 may include an insulating resin that is resistant to heat and a solvent. The line banks 17 and the banks 18 may be formed by processing an insulating resin into a desired pattern by means of photolithography and developing, for example. The line banks 17 may each have a forward tapered shape or an inversely tapered shape tapering at the bottom in cross-sectional view. The banks 18 may each have a forward tapered shape or an inverse tapered shape tapering at the bottom in cross-sectional view.

In Modification Example B, the interface 28S between the protection layer 28A and the sealing layer 28B that are provided on the cathode 27 may have the recess 28S1 opposed to the light-emitting region 24A, as in the foregoing example embodiment. This allows light emitted obliquely from the light-emitting region 24A to be raised in a frontal direction. Accordingly, it is possible to improve the front luminance.

### Modification Example C

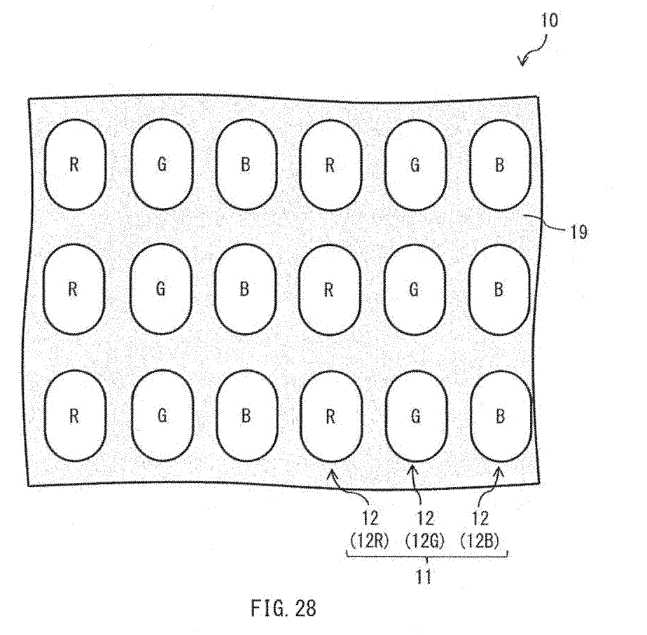

With reference to FIG. 28, for example, the organic electroluminescent panel 10 of the organic electroluminescent unit 1 according to Modification Example B may include a pixel bank 19, in place of the line banks 17 and the banks 18, on the substrate 16. The pixel bank 19 may have the openings 14A for the respective subpixels 12.

The pixel bank 19 may surround each of the pixels 11. The pixel bank 19 may define each of the pixels 11, and may partition the pixels 11 into the subpixels 12. Each region surrounded by the pixel bank 19 may correspond to each of the subpixels 12. The organic electroluminescent element 12-2 may be disposed in each of the subpixels 12. In other words, the organic electroluminescent element 12-2 in each of the subpixels 12 may be disposed in the region surrounded by the pixel bank 19.

In Modification Example C, the interface 28S between the protection layer 28A and the sealing layer 28B that are provided on the cathode 27 may have the recess 28S1 opposed to the light-emitting region 24A, as in the foregoing example embodiment. This allows light emitted obliquely from the light-emitting region 24A to be raised in a frontal direction. Accordingly, it is possible to improve the front luminance.

### 3. APPLICATION EXAMPLES

### Application Example 1

Described below is an application example of the organic electroluminescent unit 1 according to any foregoing example embodiment or modification example of the disclosure. The organic electroluminescent unit 1 is applicable to a variety of display units of electronic apparatuses that display images or pictures based on external or internal image signals. Specific but non-limiting examples of the electronic apparatuses may include television apparatuses, digital cameras, notebook personal computers, sheet-like personal computers, portable terminal devices such as mobile phones, and video cameras.

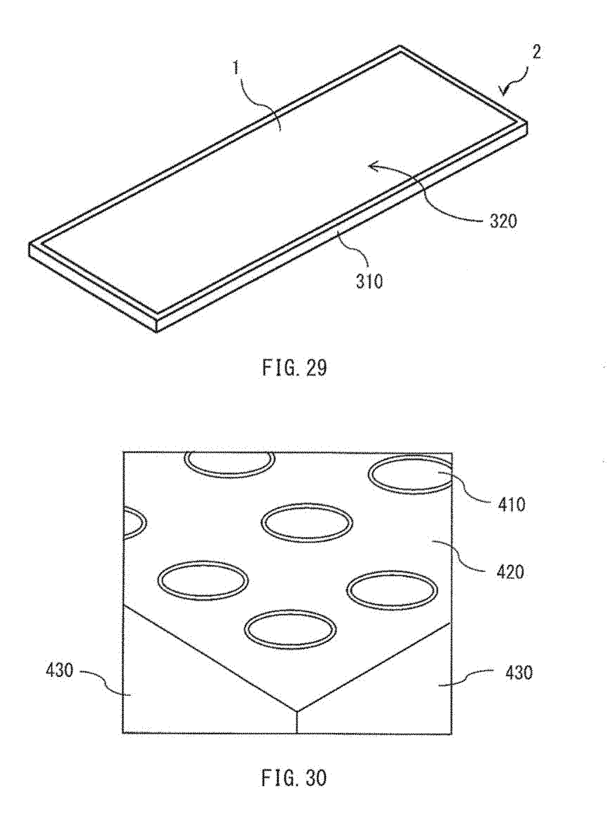

FIG. 29 is a perspective view of an electronic apparatus 2 having an example appearance according to Application Example 1. The electronic apparatus 2 may be, for example, a sheet-like personal computer that includes a body 310 having a display surface 320 on a main face. The organic electroluminescent unit 1 according to any foregoing example embodiment or modification example of the disclosure may be provided on the display surface 320 of the electronic apparatus 2. The organic electroluminescent unit 1 may be disposed with the organic electroluminescent panel 10 facing outward. The electronic apparatus 2 of Application Example 1, which includes the organic electroluminescent unit 1 according to any foregoing example embodiment or modification example of the disclosure on the display surface 320, exhibits high light emission efficiency.

### Application Example 2

Described below is an application example of the organic electroluminescent element 12-2 according to any foregoing example embodiment or modification example of the disclosure. The organic electroluminescent element 12-2 is applicable to a variety of light sources in illumination apparatuses for table lightings, or floor lightings, and room lightings.

FIG. 30 illustrates an example appearance of an illumination apparatus for a room lighting that is provided with the organic electroluminescent element 12-2 according to any foregoing example embodiment or modification example. The illumination apparatus may include, for example, illuminating sections 410 each including one or more organic electroluminescent elements 12-2 according to any foregoing example embodiment or modification example. An appropriate number of the illuminating sections 410 are disposed at appropriate intervals on a ceiling 420. Note that the illuminating sections 410 may be installed on any place, such as a wall 430 or a non-illustrated floor, other than the ceiling 420, depending on the intended use.

The illumination apparatus may perform illumination with light emitted from the organic electroluminescent element 12-2 according to any foregoing example embodiment or modification example of the disclosure. This allows the illumination apparatus to exhibit high light emission efficiency.

Although the disclosure is described hereinabove with reference to the example embodiments and modification examples, these embodiments and modification examples are not to be construed as limiting the scope of the disclosure and may be modified in a wide variety of ways. It should be appreciated that the effects described herein are mere examples. Effects of an example embodiment and modification examples of the disclosure are not limited to those described herein. The disclosure may further include any effects other than those described herein. It is possible to achieve at least the following configurations from the above-described example embodiments of the disclosure.

(1) An organic electroluminescent element including, in order, on a substrate:

a first electrode layer;

a light-emitting layer;

a second electrode layer;

a first refractive index layer; and

a second refractive index layer,

the first refractive index layer and the second refractive index layer being in contact with each other to form an interface,

the light-emitting layer having a light-emitting region opposed to the first electrode layer,

the interface having a recess opposed to the light-emitting region.

(2) The organic electroluminescent element according to (1), in which the first refractive index layer has a refractive index less than a refractive index of the second refractive index layer.

(3) The organic electroluminescent element according to (1) or (2), in which

the first refractive index layer includes an inorganic material, and

the second refractive index layer includes a resin material.

(4) The organic electroluminescent element according to any one of (1) to (3), further including a pedestal on the substrate,

the pedestal surrounding the light-emitting region and having an upper surface positioned above the light-emitting region,

the recess conforming to a surface of the pedestal.

(5) The organic electroluminescent element according to (4), in which the recess has a bottom positioned below a position of the upper surface of the pedestal.

(6) The organic electroluminescent element according to any one of (1) to (5), in which the recess has a bulge on a side face, the bulge protruding in a direction remote from the substrate.

(7) The organic electroluminescent element according to any one of (1) to (6), in which

the pedestal has an opening opposed to the light-emitting region, and

the opening has an aspect ratio of 0.8 or greater.

(8) The organic electroluminescent element according to any one of (1) to (7), in which the pedestal has a reflective side face that reflects light emitted obliquely from the light-emitting region toward a normal direction of the substrate.

(9) An organic electroluminescent panel including a plurality of pixels, the pixels each including an organic electroluminescent element, the organic electroluminescent element including, in order;

a substrate;

a first electrode layer;

a light-emitting layer;

a second electrode layer;

a first refractive index layer; and

a second refractive index layer,

the first refractive index layer and the second refractive index layer being in contact with each other at an interface,

the light-emitting layer having one or more light-emitting regions opposed to the first electrode layer,

the interface having one or more recesses opposed to the one or more light-emitting regions.

(10) The organic electroluminescent panel according to (9), in which

the one or more recesses of the interface in each of the pixels include a plurality of recesses, and

the first refractive index layer and the second refractive index layer are shared between the plurality of recesses in each of the pixels.

(11) The organic electroluminescent panel according to (9) or (10), in which

the pixels each include a pedestal surrounding the one or more light-emitting regions and having an upper surface positioned above the one or more light-emitting regions, and

the one or more recesses conform to a surface of the pedestal and have a bottom positioned below the upper surface of the pedestal.

(12) The organic electroluminescent panel according to any one of (9) to (11), in which

the one or more light-emitting regions of the light-emitting layer in each of the pixels include a plurality of light-emitting regions each having a strip shape, and

the pedestal is provided between two of the light-emitting regions that are adjacent to each other.

(13) The organic electroluminescent panel according to (9) to (11), in which

the one or more light-emitting regions of the light-emitting layer in each of the pixels include a plurality of light-emitting regions each having an island shape, and

the pedestal surrounds the light-emitting regions.

(14) An electronic apparatus including an organic electroluminescent panel including a plurality of pixels, the pixels each including an organic electroluminescent element, and a driving circuit configured to drive the organic electroluminescent panel,

the organic electroluminescent element including, in order:

a substrate;

a first electrode layer;

a light-emitting layer;

a second electrode layer;

a first refractive index layer; and

a second refractive index layer,

the first refractive index layer and the second refractive index layer being in contact with each other at an interface,

the light-emitting layer having a light-emitting region opposed to the first electrode layer,

the interface having a recess opposed to the light-emitting region.

In the organic electroluminescent element, the organic electroluminescent panel, and the electronic apparatus according to an example embodiment of the disclosure, the interface between the first refractive index layer provided on the second electrode layer and the second refractive index layer may have the recess opposed to the light-emitting region. This allows light emitted obliquely from the light-emitting region to be raised in a frontal direction.

In the organic electroluminescent element, the organic electroluminescent panel, and the electronic apparatus according to an example embodiment of the disclosure, light emitted obliquely from the light-emitting region is raised in a frontal direction. Accordingly, it is possible to improve the front luminance. Note that effects of the example embodiment of the disclosure are not limited to the effect described hereinabove, and may be any effect described herein.

Although the disclosure is described hereinabove in terms of example embodiments and modification examples, it is not limited thereto. It should be appreciated that variations may be made in the example embodiments and modification examples described herein by persons skilled in the art without departing from the scope of the disclosure as defined by the following claims. The limitations in the claims are to be interpreted broadly based on the language employed in the claims and not limited to examples described in this specification or during the prosecution of the application, and the examples are to be construed as non-exclusive. For example, in this disclosure, the use of the terms first, second, etc. do not denote any order or importance, but rather the terms first, second, etc., are used to distinguish one element from another. The term “disposed on/provided on/formed on” and its variants as used herein refer to elements disposed directly in contact with each other or indirectly by having intervening structures therebetween. Moreover, no element or component in this disclosure is intended to be dedicated to the public regardless of whether the element or component is explicitly recited in the following claims.

What is claimed is:

1. An organic electroluminescent element comprising, in order, on a substrate:
a first electrode layer;
a light-emitting layer;
a second electrode layer;
a first refractive index layer; and
a second refractive index layer,
the first refractive index layer and the second refractive index layer being in contact with each other to form an interface,
the light-emitting layer having a light-emitting region opposed to the first electrode layer,
the interface having a recess opposed to the light-emitting region.

2. The organic electroluminescent element according to claim 1, wherein the first refractive index layer has a refractive index less than a refractive index of the second refractive index layer.

3. The organic electroluminescent element according to claim 1, wherein
the first refractive index layer includes an inorganic material, and
the second refractive index layer includes a resin material.

4. The organic electroluminescent element according to claim 1, further comprising a pedestal on the substrate,
the pedestal surrounding the light-emitting region and having an upper surface positioned above the light-emitting region,
the recess conforming to a surface of the pedestal.

5. The organic electroluminescent element according to claim 4, wherein the recess has a bottom positioned below the upper surface of the pedestal.

6. The organic electroluminescent element according to claim 1, wherein the recess has a bulge on a side face, the bulge protruding in a direction remote from the substrate.

7. The organic electroluminescent element according to claim 1, wherein
the pedestal has an opening opposed to the light-emitting region, and
the opening has an aspect ratio of 0.8 or greater.

8. The organic electroluminescent element according to claim 1, wherein the pedestal has a reflective side face that reflects light emitted obliquely from the light-emitting region toward a normal direction of the substrate.

9. An organic electroluminescent panel including a plurality of pixels, the pixels each including an organic electroluminescent element, the organic electroluminescent element comprising, in order, on a substrate:
a first electrode layer;
a light-emitting layer;
a second electrode layer;
a first refractive index layer; and
a second refractive index layer,
the first refractive index layer and the second refractive index layer being in contact with each other at an interface,
the light-emitting layer having one or more light-emitting regions opposed to the first electrode layer,
the interface having one or more recesses opposed to the one or more light-emitting regions.

10. The organic electroluminescent panel according to claim 9, wherein
the one or more recesses of the interface in each of the pixels comprise a plurality of recesses, and
the first refractive index layer and the second refractive index layer are shared between the plurality of recesses in each of the pixels.

11. The organic electroluminescent panel according to claim 9, wherein
the pixels each include a pedestal surrounding the one or more light-emitting regions and having an upper surface positioned above the one or more light-emitting regions, and
the one or more recesses conform to a surface of the pedestal and have a bottom positioned below the upper surface of the pedestal.

12. The organic electroluminescent panel according to claim 9, wherein
the one or more light-emitting regions of the light-emitting layer in each of the pixels comprise a plurality of light-emitting regions each having a strip shape, and
the pedestal is provided between two of the light-emitting regions that are adjacent to each other.

13. The organic electroluminescent panel according to claim 9, wherein
the one or more light-emitting regions of the light-emitting layer in each of the pixels comprise a plurality of light-emitting regions each having an island shape, and
the pedestal surrounds the light-emitting regions.

14. An electronic apparatus including an organic electroluminescent panel including a plurality of pixels, the pixels each including an organic electroluminescent element, and a driving circuit configured to drive the organic electroluminescent panel,
the organic electroluminescent element comprising, in order on a substrate:
a first electrode layer;
a light-emitting layer;
a second electrode layer;
a first refractive index layer; and
a second refractive index layer,
the first refractive index layer and the second refractive index layer being in contact with each other at an interface,
the light-emitting layer having a light-emitting region opposed to the first electrode layer,
the interface having a recess opposed to the light-emitting region.
